(19) United States
(12) Patent Application Publication
(10) Pub. No.: US 2024/0074320 A1
(43) Pub. Date: Feb. 29, 2024

(54) PIEZOELECTRIC ELEMENT

(71) Applicant: TDK CORPORATION, Tokyo (JP)

(72) Inventors: Shuto ONO, Tokyo (JP); Satoshi SASAKI, Tokyo (JP); Yasuyuki SATOH, Tokyo (JP); Keiji OGUCHI, Tokyo (JP)

(73) Assignee: TDK CORPORATION, Tokyo (JP)

(21) Appl. No.: 18/454,341

(22) Filed: Aug. 23, 2023

(30) Foreign Application Priority Data
Aug. 26, 2022 (JP) 2022-135008

(51) Int. Cl. H10N 30/87

(52) U.S. Cl. CPC H10N 30/87

(57) ABSTRACT

A piezoelectric element includes a piezoelectric body and first, second, third, and fourth electrode layers disposed in the piezoelectric body. Each of the first, second, third, and fourth electrode layers includes a pair of first electrodes and a pair of second electrodes. The first and second electrodes included in the first electrode layer oppose the second and first electrodes included in the second electrode layer, respectively, with a part of the piezoelectric body. The first and second electrodes included in the second electrode layer oppose the first and second electrodes included in the third electrode layer, respectively, with a part of the piezoelectric body. The first and second electrodes included in the third electrode layer oppose the second and first electrodes included in the fourth electrode layer, respectively, with a part of the piezoelectric body.

### CROSS-REFERENCE TO RELATED APPLICATIONS

This application is based upon and claims the benefit of priority from Japanese Patent Application No. 2022-135008, filed on Aug. 26, 2022. The entire contents of which are incorporated herein by reference.

### BACKGROUND

### Field

The present disclosure relates to a piezoelectric element.

### Description of the Related Art

Known piezoelectric elements include a piezoelectric body and a plurality of electrode layers disposed in the piezoelectric body (for example, refer to Japanese Patent No. 4069161). The plurality of electrode layers include, for example, a pair of electrode layers adjacent to each other. One of the pair of electrode layers includes a plurality of electrodes, and the other of the pair of electrode layers includes one electrode opposing the plurality of electrodes.

### SUMMARY

A piezoelectric element according to an aspect of the present disclosure includes a piezoelectric body, and at least one electrode layer group including a first electrode layer, a second electrode layer, a third electrode layer, and a fourth electrode layer disposed in the piezoelectric body. Each of the first electrode layer, the second electrode layer, the third electrode layer, and the fourth electrode layer includes a pair of first electrodes physically and electrically separated from each other in the piezoelectric body, and a pair of second electrodes physically and electrically connected to each other in the piezoelectric body. The first electrodes included in the first electrode layer oppose the second electrodes included in the second electrode layer with a part of the piezoelectric body. The second electrodes included in the first electrode layer oppose the first electrodes included in the second electrode layer with a part of the piezoelectric body. The first electrodes included in the second electrode layer oppose the first electrodes included in the third electrode layer with a part of the piezoelectric body. The second electrodes included in the second electrode layer oppose the second electrodes included in the third electrode layer with a part of the piezoelectric body. The first electrodes included in the third electrode layer oppose the second electrodes included in the fourth electrode layer with a part of the piezoelectric body. The second electrodes included in the third electrode layer oppose the first electrodes included in the fourth electrode layer with a part of the piezoelectric body.

In the one aspect, each of the first electrode layer, the second electrode layer, the third electrode layer, and the fourth electrode layer includes the pair of first electrodes and the pair of second electrodes. Therefore, as compared with a configuration in which one of a pair of electrode layers includes a plurality of electrodes and the other of the pair of electrode layers includes one electrode opposing the plurality of electrodes, the one aspect increases a degree of freedom of a magnitude of an electric potential applied to each electrode layer. As a result, the one aspect improves drive characteristics of the piezoelectric element.

In the one aspect, the piezoelectric body may include a first main surface and a second main surface opposing each other in a first direction, a first side surface and a second side surface opposing each other in a second direction, and a first end surface and a second end surface opposing each other in a third direction. Each of the first electrode layer, the second electrode layer, the third electrode layer, and the fourth electrode layer may include a plurality of first connection conductors exposed at the first side surface and a plurality of second connection conductors exposed at the second side surface. Each of the plurality of first connection conductors may be exposed at the first side surface at different positions in the third direction. Each of the plurality of second connection conductors may be exposed at the second side surface at different positions in the third direction. In each of the first electrode layer, the second electrode layer, the third electrode layer, and the fourth electrode layer, each of one of the pair of first electrodes and one of the pair of second electrodes may be adjacent to the first side surface and physically and electrically connected to a corresponding first connection conductor among the plurality of first connection conductors. In each of the first electrode layer, the second electrode layer, the third electrode layer, and the fourth electrode layer, each of another of the pair of first electrodes and another of the pair of second electrodes may be adjacent to the second side surface and physically and electrically connected to a corresponding second connection conductor among the plurality of second connection conductors.

In the configuration in which each of the first, second, third, and fourth electrode layer includes the plurality of first and second connection conductors, the degree of freedom of the magnitude of the electric potential applied to each electrode layer further increases. As a result, this configuration certainly improves the drive characteristics of the piezoelectric element.

In the one aspect, a first shortest distance between the first connection conductor connected to the one of the pair of second electrodes and the second connection conductor connected to the other of the pair of second electrodes in the first electrode layer and the third electrode layer may be different from a second shortest distance between the second connection conductor connected to the one of the pair of second electrodes and the first connection conductor connected to the other of the pair of second electrodes in the second electrode layer and the fourth electrode layer.

In the configuration in which the first shortest distance and the second shortest distance are different from each other, the degree of freedom of the magnitude of the electric potential applied to each electrode layer further increases. As a result, this configuration more certainly improves the drive characteristics of the piezoelectric element.

In the one aspect, the first shortest distance may be smaller than the second shortest distance.

In the configuration in which the first shortest distance is smaller than the second shortest distance, the degree of freedom of the magnitude of the electric potential applied to each electrode layer further increases. As a result, this configuration still more certainly improves the drive characteristics of the piezoelectric element.

The one aspect may include a first external electrode, a second external electrode, a third external electrode, and a fourth external electrode disposed on the first side surface, and a fifth external electrode, a sixth external electrode, a seventh external electrode, and an eighth external electrode disposed on the second side surface. The first external electrode may be connected to the first connection conductor included in the second electrode layer and connected to the one of the pair of first electrodes, and may be connected to the first connection conductor included in the fourth electrode layer and connected to the one of the pair of second electrodes. The second external electrode may be connected to the first connection conductor included in the first electrode layer and connected to the one of the pair of second electrodes, and may be connected to the first connection conductor included in the third electrode layer and connected to the one of the pair of first electrodes. The third external electrode may be connected to the first connection conductor included in the first electrode layer and connected to the one of the pair of first electrodes, and may be connected to the first connection conductor included in the third electrode layer and connected to the one of the pair of second electrodes. The fourth external electrode may be connected to the first connection conductor included in the second electrode layer and connected to the one of the pair of second electrodes, and may be connected to the first connection conductor included in the fourth electrode layer and connected to the one of the pair of first electrodes. The fifth external electrode may be connected to the second connection conductor included in the second electrode layer and connected to the other of the pair of second electrodes, and may be connected to the second connection conductor included in the fourth electrode layer and connected to the other of the pair of first electrodes. The sixth external electrode may be connected to the second connection conductor included in the first electrode layer and connected to the other of the pair of first electrodes, and may be connected to the second connection conductor included in the third electrode layer and connected to the other of the pair of second electrodes. The seventh external electrode may be connected to the second connection conductor included in the first electrode layer and connected to the other of the pair of second electrodes, and may be connected to the second connection conductor included in the third electrode layer and connected to the other of the pair of first electrodes. The eighth external electrode may be connected to the second connection conductor included in the second electrode layer and connected to the other of the pair of first electrodes, and may be connected to the second connection conductor included in the fourth electrode layer and connected to the other of the pair of second electrodes.

In the configuration including the first to eighth external electrodes, each of the first to fourth external electrodes being connected to the corresponding first connection conductor among the plurality of first connection conductors, and each of the fifth to eighth external electrodes being connected to the corresponding second connection conductor among the plurality of second connection conductors, a voltage is applied to the connection conductors included in each electrode layer through the first to eighth external electrodes.

In the one aspect, the first external electrode, the second external electrode, the third external electrode, and the fourth external electrode may be positioned in the order of the first external electrode, the second external electrode, the third external electrode, and the fourth external electrode in a direction from the first end surface toward the second end surface of the third direction. The fifth external electrode, the sixth external electrode, the seventh external electrode, and the eighth external electrode may be positioned in the order of the fifth external electrode, the sixth external electrode, the seventh external electrode, and the eighth external electrode in the direction from the first end surface toward the second end surface.

In the configuration in which the first to eighth external electrodes are positioned in the above-described order, a magnitude of the electric potential applied to each electrode layer tends to be easily controlled through the first to eighth external electrodes.

In the one aspect, in the second electrode layer and the third electrode layer, the one of the pair of second electrodes and the other of the pair of first electrodes may be adjacent to the first end surface, and the one of the pair of first electrodes and the other of the pair of second electrodes may be adjacent to the second end surface. In the first electrode layer and the fourth electrode layer, the other of the pair of first electrodes and the one of the pair of second electrodes may be adjacent to the first end surface, and the other of the pair of second electrodes and the one of the pair of first electrodes may be adjacent to the second end surface.

In the second electrode layer and the third electrode layer, the one of the second electrodes and the other of the first electrodes are adjacent to the first end surface, and the one of the first electrodes and the other of the second electrodes are adjacent to the second end surface. In the first electrode layer and the fourth electrode layer, the other of the first electrodes and the one of the second electrodes are adjacent to the first end surface, and the other of the second electrodes and the one of the first electrodes are adjacent to the second end surface. The configuration more certainly improves the drive characteristics of the piezoelectric element.

In the one aspect, each of the first electrodes may include a pair of first end edges opposing each other in the third direction. Each of the second electrodes may include a pair of second end edges opposing each other in the third direction. Each of the first connection conductors may include a pair of third end edges opposing each other in the third direction. Each of the second connection conductors may include a pair of fourth end edges opposing each other in the third direction. In the first electrode and the first connection conductor connected to each other, positions of the pair of first end edges in the third direction may be different from positions of the pair of third end edges in the third direction. In the second electrode and the first connection conductor connected to each other, positions of the pair of second end edges in the third direction may be different from positions of the pair of third end edges in the third direction. In the first electrode and the second connection conductor connected to each other, positions of the pair of first end edges in the third direction may be different from positions of the pair of fourth end edges in the third direction. In the second electrode and the second connection conductor connected to each other, positions of the pair of second end edges in the third direction may be different from positions of the pair of fourth end edges in the third direction.

In the first electrode and the first connection conductor connected to each other, the positions of the pair of first end edges are different from the positions of the pair of third end edges in the third direction, in the second electrode and the first connection conductor connected to each other, the positions of the pair of second end edges are different from the positions of the pair of third end edges in the third direction, in the first electrode and the second connection conductor connected to each other, the positions of the pair of first end edges are different from the positions of the pair of fourth end edges in the third direction, and in the second electrode and the second connection conductor connected to each other, the positions of the pair of second end edges are different from the positions of the pair of fourth end edges in the third direction. The configuration still more certainly improves the drive characteristics of the piezoelectric element.

In the one aspect, the at least one electrode layer group includes a plurality of electrode layer groups each including the first electrode layer, the second electrode layer, the third electrode layer, and the fourth electrode layer. The fourth electrode layer included in one of the plurality of electrode layer groups and the first electrode layer included in another of the plurality of electrode layer groups may be adjacent to each other.

In the configuration in which the fourth electrode layer included in the one of the plurality of electrode layer groups and the first electrode layer included in the other of the plurality of electrode layer groups are adjacent to each other, the drive characteristics of the piezoelectric element is still more certainly improved.

The present disclosure will become more fully understood from the detailed description given hereinafter and the accompanying drawings which are given by way of illustration only, and thus are not to be considered as limiting the present disclosure.

Further scope of applicability of the present disclosure will become apparent from the detailed description given hereinafter. However, it should be understood that the detailed description and specific examples, while indicating examples of the disclosure, are given by way of illustration only, since various changes and modifications within the spirit and scope of the disclosure will become apparent to those skilled in the art from this detailed description.

### BRIEF DESCRIPTION OF THE DRAWINGS

FIG. 1 is a perspective view illustrating a piezoelectric element according to an example;

FIG. 2 is a diagram illustrating a cross-sectional configuration of the piezoelectric element according to the present example;

FIG. 3 is a diagram illustrating a cross-sectional configuration of the piezoelectric element according to the present example;

FIG. 4 is a diagram illustrating an electrode layer;

FIG. 5 is a diagram illustrating an electrode layer;

FIG. 6 is a diagram illustrating an electrode layer;

FIG. 7 is a diagram illustrating an electrode layer;

FIG. 8 is a diagram illustrating an electrically conductive line; and

FIG. 9 is a diagram illustrating an electrically conductive line.

### DETAILED DESCRIPTION

Hereinafter, examples of the present disclosure will be described in detail with reference to the accompanying drawings. In the following description, the same elements or elements having the same functions are denoted with the same reference numerals and overlapped explanation is omitted.

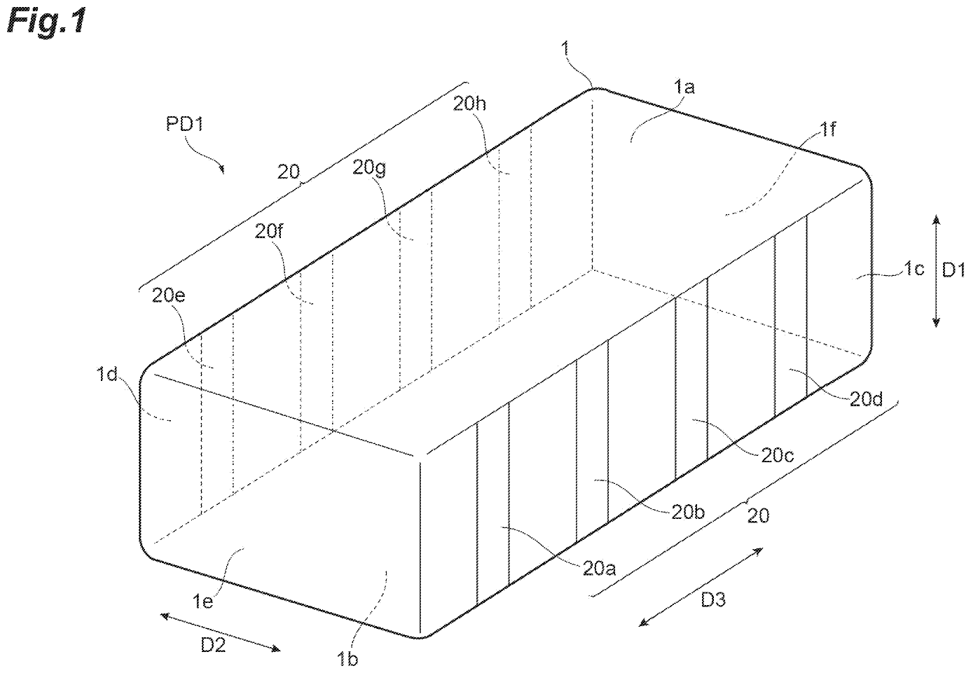

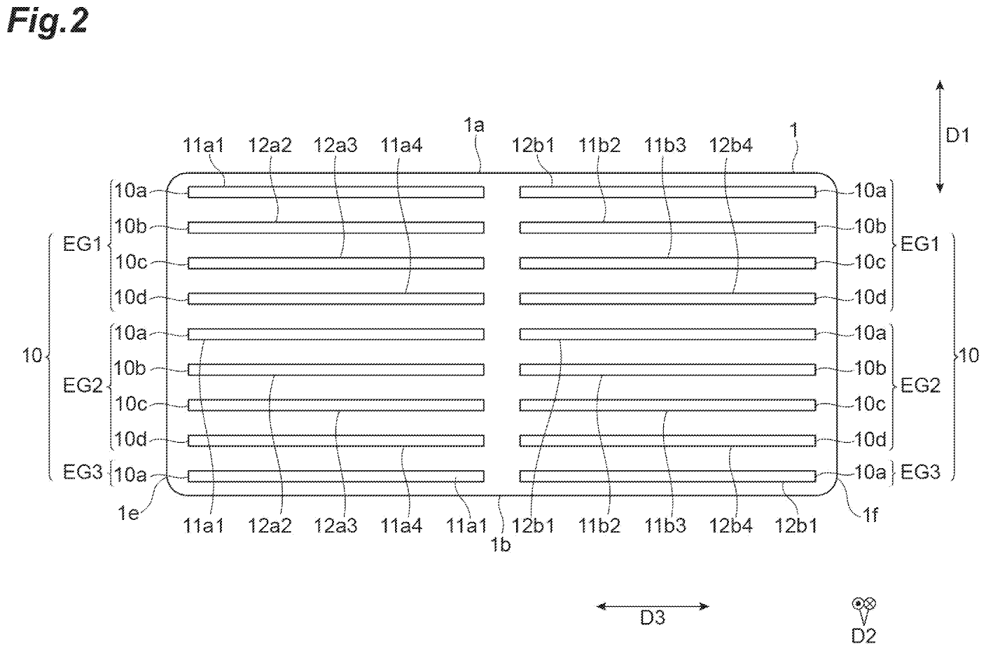

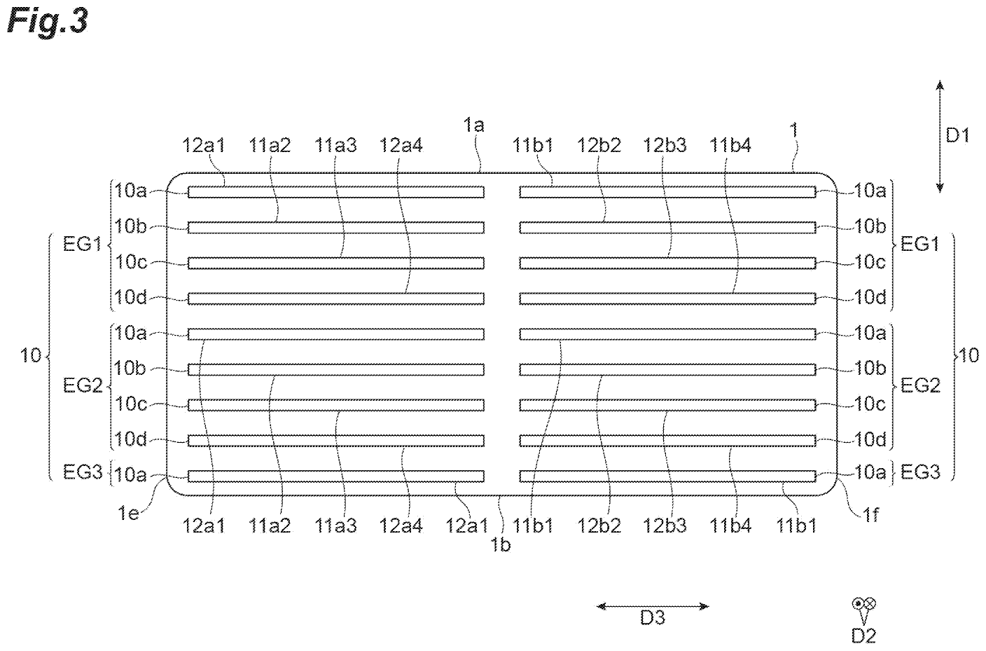

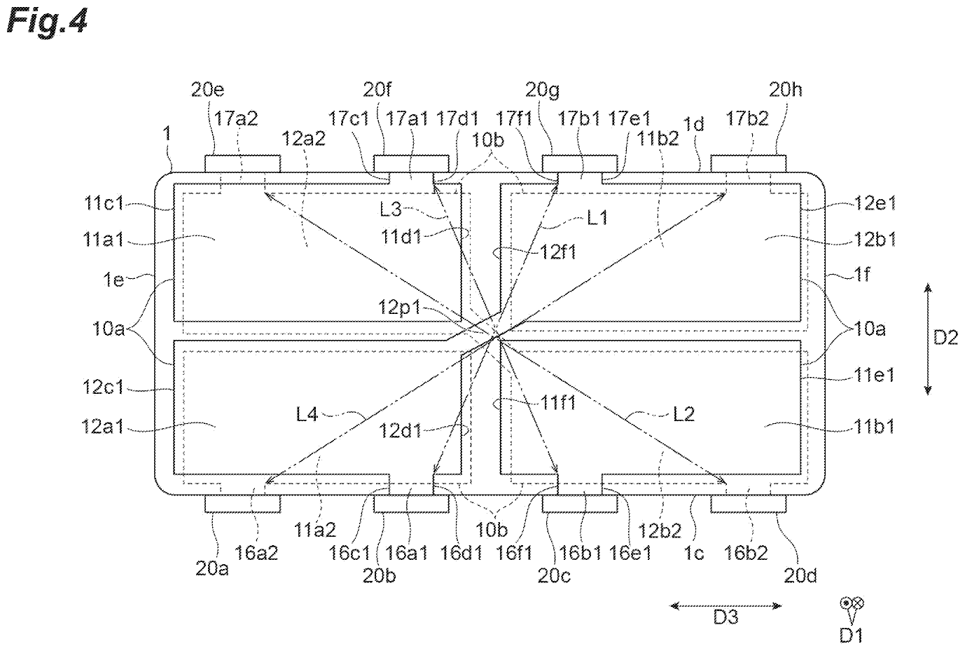

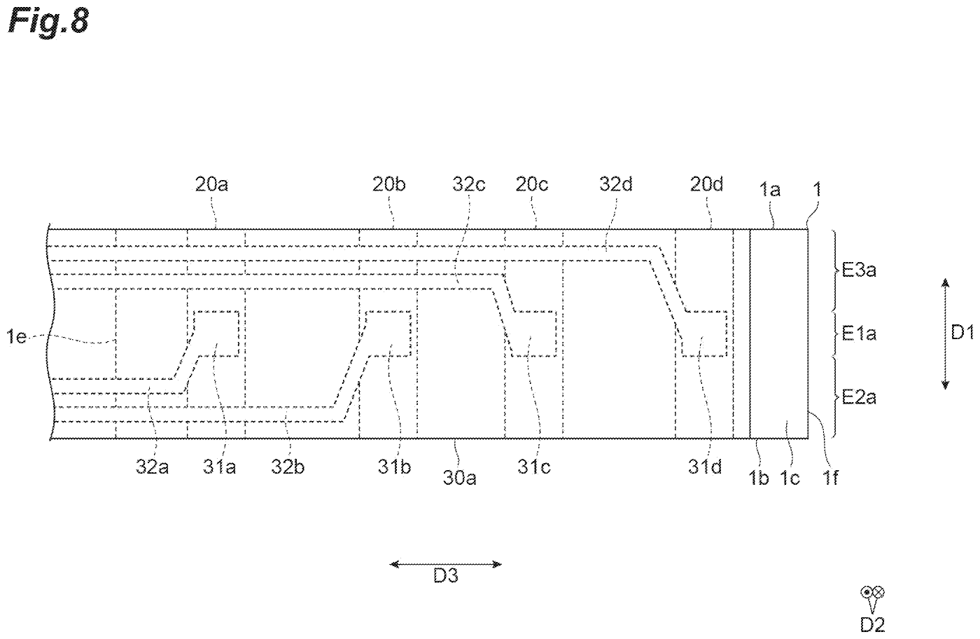

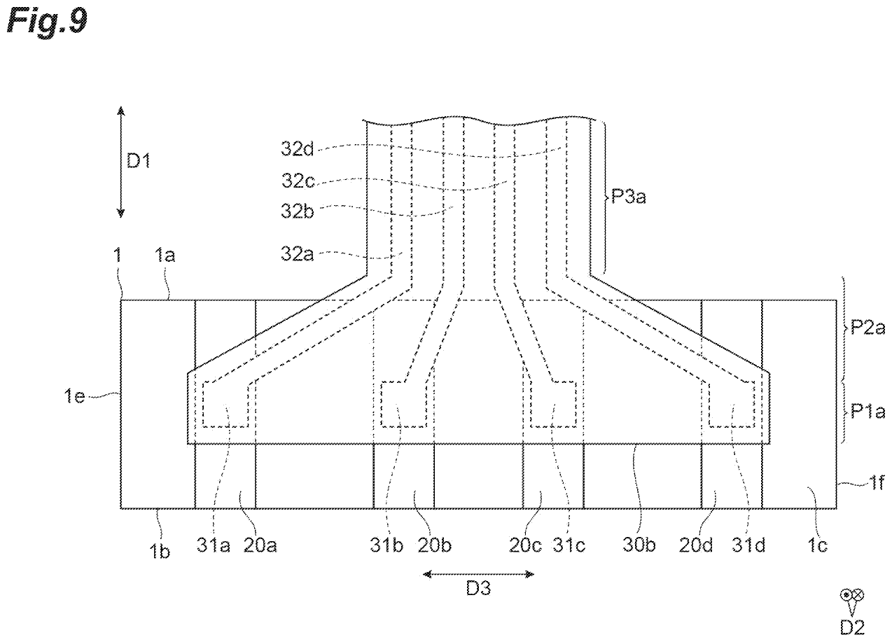

A piezoelectric element according to the present example will be described with reference to FIGS. 1 to 9. FIG. 1 is a perspective view illustrating the piezoelectric element according to the present example. FIGS. 2 and 3 are diagrams illustrating a cross-sectional configuration of the piezoelectric element according to the present example. FIGS. 4 to 7 are diagrams illustrating an electrode layer. FIGS. 8 and 9 are diagrams illustrating an electrically conductive line.

As illustrated in FIGS. 1 to 3, a piezoelectric element PD1 includes a piezoelectric body 1, a plurality of electrode layers 10, and a plurality of external electrodes 20. The plurality of electrode layers 10 is disposed in the piezoelectric body 1. The plurality of external electrodes disposed on an outer surface of the piezoelectric body 1. Each of the electrode layers 10 is electrically connected to the corresponding external electrode 20 among the plurality of external electrodes 20. The piezoelectric element PD1 is used as, for example, a piezoelectric actuator. The piezoelectric element PD1 vibrates, for example, due to an application of an AC voltage. In FIGS. 2 and 3, hatching is omitted to clearly illustrate each part.

In the present example, the piezoelectric body 1 has a rectangular parallelepiped shape. The piezoelectric body 1 includes a main surface 1a and a main surface 1b opposing each other in a first direction D1, a side surface 1c and a side surface 1d opposing each other in a second direction D2, and an end surface 1e and an end surface 1f opposing each other in a third direction D3. The second direction D2 intersects the first direction D1. The third direction D3 intersects the first direction D1 and the second direction D2. In the present example, the first direction D1, the second direction D2, and the third direction D3 are orthogonal to each other. The main surfaces 1a and 1b, the side surfaces 1c and 1d, and the end surfaces 1e and 1f have, for example, rectangular shapes. The “rectangular parallelepiped shape” in the present specification includes a rectangular parallelepiped shape in which corner portions and ridge portions are chamfered, or a rectangular parallelepiped shape in which corner portions and ridge portions are rounded. The “rectangular shape” in the present specification includes, for example, a shape in which each corner is chamfered or a shape in which each corner is rounded. For example, when the main surface 1a includes a first main surface, the main surface 1b includes a second main surface. For example, when the side surface 1c includes a first side surface, the side surface 1d includes a second side surface. For example, when the end surface 1e includes a first end surface, the end surface 1f includes a second end surface.

The main surfaces 1a and 1b define both ends of the piezoelectric body 1 in the first direction D1. The side surfaces 1c and 1d are adjacent to the main surfaces 1a and 1b and define both ends of the piezoelectric body 1 in the second direction D2. The end surfaces 1e and 1f are adjacent to the main surfaces 1a and 1b and the side surfaces 1c and 1d, and define both ends of the piezoelectric body 1 in the third direction D3. The main surfaces 1a and 1b extend in the second direction D2 to couple the side surface 1c and the side surface 1d. The main surfaces 1a and 1b extend in the third direction D3 to couple the end surface 1e and the end surface 1f. The side surfaces 1c and 1d extend in the first direction D1 to couple the main surface 1a and the main surface 1b. The side surfaces 1c and 1d extend in the third direction D3 to couple the end surface 1e and the end surface 1f. The end surfaces 1e and 1f extend in the first direction D1 to couple the main surface 1a and the main surface 1b. The end surfaces 1e and 1f extend in the second direction D2 to couple the side surface 1c and the side surface 1d. The main surfaces 1a and 1b, the side surfaces 1c and 1d, and the end surfaces 1e and 1f may be indirectly adjacent to each other. In the configuration, a ridge portion is located between the main surfaces 1a and 1b, the side surfaces 1c and 1d, and the end surfaces 1e and 1f.

A length of the piezoelectric body 1 in the first direction D1 is, for example, 8 mm A length of the piezoelectric body 1 in the second direction D2 is, for example, 2 mm. A length of the piezoelectric body 1 in the third direction D3 is, for example, 2 mm. In the piezoelectric body 1, for example, the third direction D3 is a long side direction.

In the present example, the piezoelectric body 1 includes, for example, a plurality of piezoelectric layers. The piezoelectric body 1 is formed due to laminating the plurality of piezoelectric layers, for example. A part of the piezoelectric body 1 includes each of the piezoelectric layers. A direction in which the plurality of piezoelectric layers are laminated is, for example, the first direction D1. Each of the piezoelectric layers includes a piezoelectric ceramic material. The piezoelectric ceramic material includes PZT[Pb(Zr, Ti)O₃], PT(PbTiO₃), PLZT[(Pb, La)(Zr, Ti)O₃], or barium titanate (BaTiO₃). Each of the piezoelectric layers includes a sintered body of a ceramic green sheet. The ceramic green sheet includes the above-described piezoelectric ceramic material. In the actual piezoelectric body 1, the plurality of piezoelectric layers are integrated to such an extent that boundaries between the piezoelectric layers cannot be visually recognized.

The piezoelectric element PD1 includes a plurality of electrode layer groups EG1, EG2, and EG3. In the present example, three electrode layer groups EG1, EG2, and EG3 are included. Each of the electrode layer group EG1 and the electrode layer group EG2 includes an electrode layer 10a, an electrode layer 10b, an electrode layer 10c, and an electrode layer 10d. The electrode layer group EG3 includes an electrode layer 10a. The piezoelectric element PD1 includes a plurality of the electrode layers 10a, a plurality of the electrode layers 10b, a plurality of the electrode layers 10c, and a plurality of the electrode layers 10d. The piezoelectric element PD1 includes the plurality of electrode layers 10.

A thickness of each of the electrode layers 10a to 10d in the first direction D1 is, for example, 0.5 to 5 μm.

In the electrode layer group EG1, the electrode layer 10b is located between the electrode layer 10a and the electrode layer 10c, and is adjacent to the electrode layer 10a and the electrode layer 10c. The electrode layer 10c is located between the electrode layer 10b and the electrode layer 10d, and is adjacent to the electrode layer 10b and the electrode layer 10d. The piezoelectric layer is positioned between the electrode layer 10a and the electrode layer 10b, between the electrode layer 10b and the electrode layer 10c, and between the electrode layer 10c and the electrode layer 10d. In the electrode layer group EG1, the electrode layers 10a, 10b, 10c, and 10d are disposed in the first direction D1 in the order of the electrode layer 10a, the electrode layer 10b, the electrode layer 10c, and the electrode layer 10d.

In the electrode layer group EG2, the electrode layer 10b is located between the electrode layer 10a and the electrode layer 10c, and is adjacent to the electrode layer 10a and the electrode layer 10c. The electrode layer 10c is located between the electrode layer 10b and the electrode layer 10d, and is adjacent to the electrode layer 10b and the electrode layer 10d. The piezoelectric layer is positioned between the electrode layer 10a and the electrode layer 10b, between the electrode layer 10b and the electrode layer 10c, and between the electrode layer 10c and the electrode layer 10d. In the electrode layer group EG2, the electrode layers 10a, 10b, 10c, and 10d are disposed in the first direction D1 in the order of the electrode layer 10a, the electrode layer 10b, the electrode layer 10c, and the electrode layer 10d.

The electrode layer 10d of the electrode layer group EG1 and the electrode layer 10a of the electrode layer group EG2 are adjacent to each other. The piezoelectric layer is positioned between the electrode layer 10d of the electrode layer group EG1 and the electrode layer 10a of the electrode layer group EG2. The electrode layer 10d of the electrode layer group EG2 and the electrode layer 10a of the electrode layer group EG3 are adjacent to each other. The piezoelectric layer is positioned between the electrode layer 10d of the electrode layer group EG2 and the electrode layer 10a of the electrode layer group EG3. In the present example, when the electrode layer 10a includes a first electrode layer, the electrode layer 10b includes a second electrode layer, the electrode layer 10c includes a third electrode layer, and the electrode layer 10d includes a fourth electrode layer.

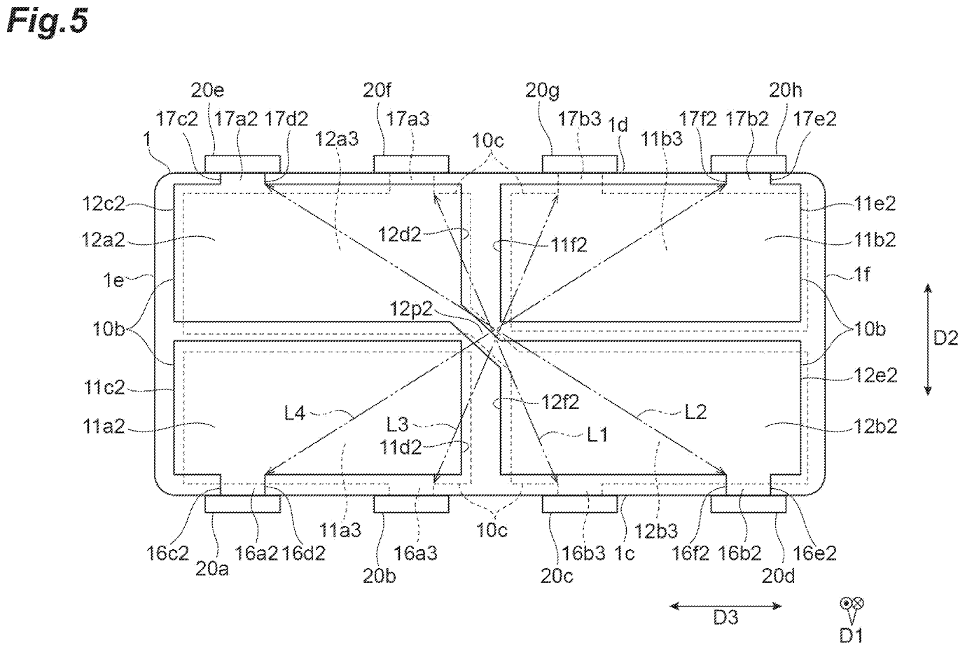

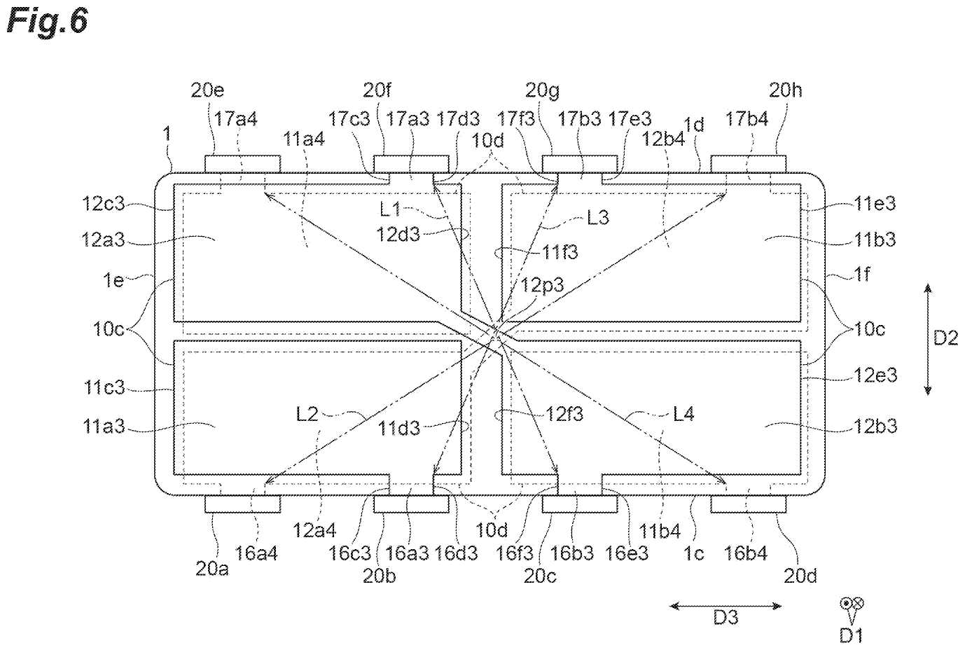

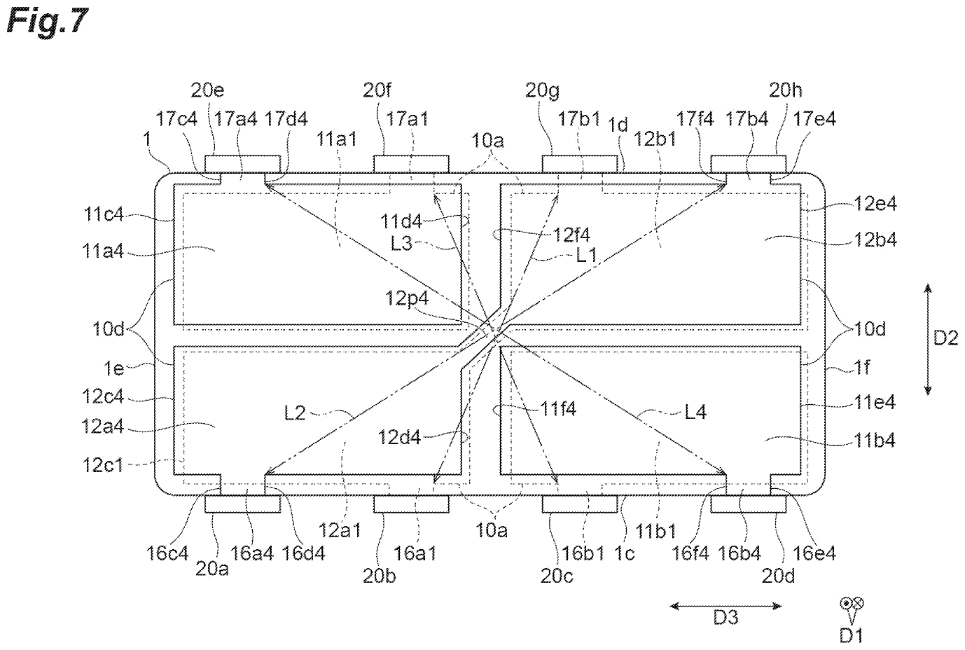

FIG. 2 illustrates a cross-sectional configuration of two electrodes, among a plurality of electrodes included in each of the electrode layers 10a to 10d, disposed closer to the side surface 1d. FIG. 3 illustrates a cross-sectional configuration of two electrodes, among a plurality of electrodes included in each of the electrode layers 10a to 10d, disposed closer to the side surface 1c. FIG. 4 illustrates a configuration of the electrode layer 10a and the electrode layer 10b. FIG. 5 illustrates a configuration of the electrode layer 10b and the electrode layer 10c. FIG. 6 illustrates a configuration of the electrode layer 10c and the electrode layer 10d. FIG. 7 illustrates a configuration of the electrode layer 10d and the electrode layer 10a. FIGS. 4 to 7 illustrate the configurations of the electrode layers 10a to 10d when viewed in a direction from the main surface 1a toward the main surface 1b in the first direction D1.

As illustrated in FIGS. 2 to 7, the electrode layers 10a includes a pair of electrodes 11a1 and 11b1 physically and electrically separated from each other in the piezoelectric body 1. The electrode layers 10b includes a pair of electrodes 11a2 and 11b2 physically and electrically separated from each other in the piezoelectric body 1. The electrode layers 10c includes a pair of electrodes 11a3 and 11b3 physically and electrically separated from each other in the piezoelectric body 1. The electrode layers 10d includes a pair of electrodes 11a4 and 11b4 physically and electrically separated from each other in the piezoelectric body 1.

The electrode layers 10a includes a pair of electrodes 12a1 and 12b1 physically and electrically connected to each other in the piezoelectric body 1. The electrode layers 10b includes a pair of electrodes 12a2 and 12b2 physically and electrically connected to each other in the piezoelectric body 1. The electrode layers 10c includes a pair of electrodes 12a3 and 12b3 physically and electrically connected to each other in the piezoelectric body 1. The electrode layers 10d includes a pair of electrodes 12a4 and 12b4 physically and electrically connected to each other in the piezoelectric body 1.

The electrode layer 10a includes a pair of electrodes 11a1 and 11b1 and a pair of electrodes 12a1 and 12b1. The electrode layer 10b includes a pair of electrodes 11a2 and 11b2 and a pair of electrodes 12a2 and 12b2. The electrode layer 10c includes a pair of electrodes 11a3 and 11b3 and a pair of electrodes 12a3 and 12b3. The electrode layer 10d includes a pair of electrodes 11a4 and 11b4 and a pair of electrodes 12a4 and 12b4. For example, when each of the electrodes 11a1, 11b1, 11a2, 11b2, 11a3, 11b3, 11a4, and 11b4 includes a first electrode, each of the electrodes 12a1, 12b1, 12a2, 12b2, 12a3, 12b3, 12a4, and 12b4 includes a second electrode.

In the present example, the piezoelectric body 1 has a rectangular shape when viewed in the first direction D1.

As illustrated in FIG. 4, when viewed in the first direction D1, the pair of electrodes 11a1 and 11b1 of the electrode layer 10a is disposed, for example, to be positioned at a first diagonal in the rectangular shape of the piezoelectric body 1. As illustrated in FIG. 7, when viewed in the first direction D1, the pair of electrodes 11a4 and 11b4 of the electrode layer 10d is disposed, for example, to be positioned at the first diagonal in the rectangular shape of the piezoelectric body 1. In FIGS. 4 and 7, the first diagonal includes a corner defined by the side surface 1d and the end surface 1e and a corner defined by the side surface 1c and the end surface 1f when viewed in the first direction D1. In the present example, the electrodes 11a1 and 11a4 are disposed at a corner defined by the side surface 1d and the end surface 1e, and the electrodes 11b1 and 11b4 are disposed at a corner defined by the side surface 1c and the end surface 1f. In FIGS. 4 and 7, for the sake of explanation, the electrode layers 10a to 10d are intentionally shifted from and the electrode layers 10d to 10a when viewed in the first direction D1. In practice, when viewed in the first direction D1, an outer edge of each of the electrode layers 10a to 10d the electrode layers 10d to 10a includes a portion overlapping each other. In FIGS. 4 and 7, hatching is omitted to clearly illustrate each part.

As illustrated in FIG. 4, when viewed in the first direction D1, the pair of electrodes 12a1 and 12b1 of the electrode layer 10a is disposed, for example, to be positioned at a second diagonal in the rectangular shape of the piezoelectric body 1. As illustrated in FIG. 7, when viewed in the first direction D1, the pair of electrodes 12a4 and 12b4 of the electrode layer 10d is disposed, for example, to be positioned at the second diagonal in the rectangular shape of the piezoelectric body 1. The second diagonal includes a corner defined by the side surface 1c and the end surface 1e and a corner defined by the side surface 1d and the end surface 1f when viewed in the first direction D1. In the present example, the electrodes 12a1 and 12a4 are disposed at a corner defined by the side surface 1c and the end surface 1e, and the electrodes 12b1 and 12b4 are disposed at a corner defined by the side surface 1d and the end surface 1f.

In the electrode layer 10a, one electrode 11b1 of the pair of electrodes 11a1 and 11b1 and one electrode 12a1 of the pair of electrodes 12a1 and 12b1 are adjacent to the side surface 1c. The other electrode 11a1 of the pair of electrodes 11a1 and 11b1 and the other electrode 12b1 of the pair of electrodes 12a1 and 12b1 are adjacent to the side surface 1d. The electrodes 12a1 and 12b1 are physically and electrically connected to each other through, for example, a connection portion 12p1. The connection portion 12p1 extends, for example, in a diagonal direction of the second diagonal. In the electrode layer 10a, for example, when the electrode 11a1 includes the other of the pair of electrodes 11a1 and 11b1, the electrode 11b1 includes one of the pair of electrodes 11a1 and 11b1. For example, when the electrode 12a1 includes one of the pair of electrodes 12a1 and 12b1, the electrode 12b1 includes the other of the pair of electrodes 12a1 and 12b1.

In the electrode layer 10d, one electrode 11b4 of the pair of electrodes 11a4 and 11b4 and one electrode 12a4 of the pair of electrodes 12a4 and 12b4 are adjacent to the side surface 1c. The other electrode 11a4 of the pair of electrodes 11a4 and 11b4 and the other electrode 12b4 of the pair of electrodes 12a4 and 12b4 are adjacent to the side surface 1d. The electrodes 12a4 and 12b4 are physically and electrically connected to each other through, for example, a connection portion 12p4. The connection portion 12p4 extends, for example, in the diagonal direction of the second diagonal. In the electrode layer 10d, for example, when the electrode 11a4 includes the other of the pair of electrodes 11a4 and 11b4, the electrode 11b4 includes one of the pair of electrodes 11a4 and 11b4. For example, when the electrode 12a4 includes one of the pair of electrodes 12a4 and 12b4, the electrode 12b4 includes the other of the pair of electrodes 12a4 and 12b4.

As illustrated in FIG. 5, the pair of electrodes 11a2 and 11b2 of the electrode layer 10b is disposed, for example, to be positioned at the second diagonal. As illustrated in FIG. 6, the pair of electrodes 11a3 and 11b3 of the electrode layer 10c is disposed, for example, to be positioned at the second diagonal. In the present example, the electrodes 11a2 and 11a3 are disposed at a corner defined by the side surface 1c and the end surface 1e, and the electrodes 11b2 and 11b3 are disposed at a corner defined by the side surface 1d and the end surface 1f.

As illustrated in FIG. 5, the pair of electrodes 12a2 and 12b2 of the electrode layer 10b is disposed, for example, to be positioned at the first diagonal. As illustrated in FIG. 6, the pair of electrodes 12a3 and 12b3 of the electrode layer 10c is disposed, for example, to be positioned at the first diagonal. In the present example, the electrodes 12a2 and 12a3 are disposed at a corner defined by the side surface 1d and the end surface 1e, and the electrodes 12b2 and 12b3 are disposed at a corner defined by the side surface 1c and the end surface 1f. In FIGS. 5 and 6, for the sake of explanation, the electrode layers 10b, 10c and the electrode layers 10c, 10d are intentionally shifted from each other when viewed in the first direction D1. In practice, when viewed in the first direction D1, an outer edge of each of the electrode layers 10b, 10c and the electrode layers 10c, 10d includes a portion overlapping each other. In FIGS. 5 and 6, hatching is omitted to clearly illustrate each part.

In the electrode layer 10b, one electrode 11a2 of the pair of electrodes 11a2 and 11b2 and one electrode 12b2 of the pair of electrodes 12a2 and 12b2 are adjacent to the side surface 1c. The other electrode 11b2 of the pair of electrodes 11a2 and 11b2 and the other electrode 12a2 of the pair of electrodes 12a2 and 12b2 are adjacent to the side surface 1d. The electrodes 12a2 and 12b2 are physically and electrically connected to each other through, for example, a connection portion 12p2. The connection portion 12p2 extends, for example, in a diagonal direction of the first diagonal. In the electrode layer 10b, for example, when the electrode 11a2 includes one of the pair of electrodes 11a2 and 11b2, the electrode 11b2 includes the other of the pair of electrodes 11a2 and 11b2. For example, when the electrode 12a2 includes the other of the pair of electrodes 12a2 and 12b2, the electrode 12b2 includes one of the pair of electrodes 12a2 and 12b2.

In the electrode layer 10c, one electrode 11a3 of the pair of electrodes 11a3 and 11b3 and one electrode 12b3 of the pair of electrodes 12a3 and 12b3 are adjacent to the side surface 1c. The other electrode 11b3 of the pair of electrodes 11a3 and 11b3 and the other electrode 12a3 of the pair of electrodes 12a3 and 12b3 are adjacent to the side surface 1d. The electrodes 12a3 and 12b3 are physically and electrically connected to each other through, for example, a connection portion 12p3. The connection portion 12p3 extends, for example, in the diagonal direction of the first diagonal. In the electrode layer 10c, for example, when the electrode 11a3 includes one of the pair of electrodes 11a3 and 11b3, the electrode 11b3 includes the other of the pair of electrodes 11a3 and 11b3. For example, when the electrode 12a3 includes the other of the pair of electrodes 12a3 and 12b3, the electrode 12b3 includes one of the pair of electrodes 12a3 and 12b3.

As illustrated in FIGS. 2 to 7, the electrode layer 10a includes a pair of electrodes 11a1 and 11b1 physically and electrically separated from each other in the piezoelectric body 1. The electrode layer 10b includes a pair of electrodes 11a2 and 11b2 physically and electrically separated from each other in the piezoelectric body 1. The electrode layer 10c includes a pair of electrodes 11a3 and 11b3 physically and electrically separated from each other in the piezoelectric body 1. The electrode layer 10d includes a pair of electrodes 11a4 and 11b4 physically and electrically separated from each other in the piezoelectric body 1.

The electrode layer 10a includes a pair of electrodes 12a1 and 12b1 physically and electrically connected to each other in the piezoelectric body 1. The electrode layer 10b includes a pair of electrodes 12a2 and 12b2 physically and electrically connected to each other in the piezoelectric body 1. The electrode layer 10c includes a pair of electrodes 12a3 and 12b3 physically and electrically connected to each other in the piezoelectric body 1. The electrode layer 10d includes a pair of electrodes 12a4 and 12b4 physically and electrically connected to each other in the piezoelectric body 1.

The electrode layer 10a includes a pair of electrodes 11a1 and 11b1 and a pair of electrodes 12a1 and 12b1. The electrode layer 10b includes a pair of electrodes 11a2 and 11b2 and a pair of electrodes 12a2 and 12b2. The electrode layer 10c includes a pair of electrodes 11a3 and 11b3 and a pair of electrodes 12a3 and 12b3. The electrode layer 10d includes a pair of electrodes 11a4 and 11b4 and a pair of electrodes 12a4 and 12b4. For example, when the electrodes 11a1, 11b1, 11a2, 11b2, 11a3, 11b3, 11a4, and 11b4 include a first electrode, the electrodes 12a1, 12b1, 12a2, 12b2, 12a3, 12b3, 12a4, and 12b4 include a second electrode.

As illustrated in FIGS. 2, 3, and 4, the electrodes 11a1 and 11b1 included in the electrode layer 10a oppose the electrodes 12a2 and 12b2 included in the electrode layer 10b, respectively, with a part of the piezoelectric body. The electrodes 12a1 and 12b1 included in the electrode layer 10a oppose the electrodes the electrodes 11a2 and 11b2 included in the electrode layer 10b, respectively, with a part of the piezoelectric body 1. The electrode 11a1 included in the electrode layer 10a opposes the electrode 12a2 included in the electrode layer 10b with the piezoelectric layer. The electrode 11b1 included in the electrode layer 10a opposes the electrode 12b2 included in the electrode layer 10b with the piezoelectric layer. The electrode 12a1 included in the electrode layer 10a opposes the electrode 11a2 included in the electrode layer 10b with the piezoelectric layer. The electrode 12b1 included in the electrode layer 10a opposes the electrode 11b2 included in the electrode layer 10b with the piezoelectric layer. Among the plurality of piezoelectric layers, a piezoelectric layer positioned between the electrode 11a1 of the electrode layer 10a and the electrode 12a2 of the electrode layer 10b, a piezoelectric layer positioned between the electrode 11b1 of the electrode layer 10a and the electrode 12b2 of the electrode layer 10b, a piezoelectric layer positioned between the electrode 12a1 of the electrode layer 10a and the electrode 11a2 of the electrode layer 10b, a piezoelectric layer positioned between the electrode 11b1 of the electrode layer 10a and the electrode 12b2 of the electrode layer 10b, and a piezoelectric layer positioned between the electrode 12b1 of the electrode layer 10a and the electrode 11b2 of the electrode layer 10b include an active region due to an application of a voltage.

As illustrated in FIGS. 2, 3, and 5, the electrodes 11a2 and 11b2 included in the electrode layer 10b oppose the electrodes 11a3 and 11b3 included in the electrode layer 10c, respectively, with a part of the piezoelectric body 1. The electrodes 12a2 and 12b2 included in the electrode layer 10b oppose the electrodes 12a3 and 12b3 included in the electrode layer 10c, respectively, with a part of the piezoelectric body 1. The electrode 11a2 included in the electrode layer 10b opposes the electrode 11a3 included in the electrode layer 10c with the piezoelectric layer. The electrode 11b2 included in the electrode layer 10b opposes the electrode 11b3 included in the electrode layer 10c with the piezoelectric layer. The electrode 12a2 included in the electrode layer 10b opposes the electrode 12a3 included in the electrode layer 10c with the piezoelectric layer. The electrode 12b2 included in the electrode layer 10b opposes the electrode 12b3 included in the electrode layer 10c with the piezoelectric layer. Among the plurality of piezoelectric layers, a piezoelectric layer positioned between the electrode 11a2 of the electrode layer 10b and the electrode 11a3 of the electrode layer 10c, a piezoelectric layer positioned between the electrode 11b2 of the electrode layer 10b and the electrode 11b3 of the electrode layer 10c, a piezoelectric layer positioned between the electrode 12a2 of the electrode layer 10b and the electrode 12a3 of the electrode layer 10c, and a piezoelectric layer positioned between the electrode 12b2 of the electrode layer 10b and the electrode 12b3 of the electrode layer 10c include an active region due to an application of a voltage.

As illustrated in FIGS. 2, 3, and 6, the electrodes 11a3 and 11b3 included in the electrode layer 10c oppose the electrodes 12a4 and 12b4 included in the electrode layer 10d, respectively, with a part of the piezoelectric body 1. The electrodes 12a3 and 12b3 included in the electrode layer 10c oppose the electrodes 11a4 and 11b4 included in the electrode layer 10d, respectively, with a part of the piezoelectric body 1. The electrode 11a3 included in the electrode layer 10c opposes the electrode 12a4 included in the electrode layer 10d with the piezoelectric layer. The electrode 11b3 included in the electrode layer 10c opposes the electrode 12b4 included in the electrode layer 10d with the piezoelectric layer. The electrode 12a3 included in the electrode layer 10c opposes the electrode 11a4 included in the electrode layer 10d with the piezoelectric layer. The electrode 12b3 included in the electrode layer 10c opposes the electrode 11b4 included in the electrode layer 10d with the piezoelectric layer. Among the plurality of piezoelectric layers, a piezoelectric layer positioned between the electrode 11a3 of the electrode layer 10c and the electrode 12a4 of the electrode layer 10d, a piezoelectric layer positioned between the electrode 11b3 of the electrode layer 10c and the electrode 12b4 of the electrode layer 10d, a piezoelectric layer positioned between the electrode 12a3 of the electrode layer 10c and the electrode 11a4 of the electrode layer 10d, and a piezoelectric layer positioned between the electrode 12b3 of the electrode layer 10c and the electrode 11b4 of the electrode layer 10d include an active region due to an application of a voltage.

As illustrated in FIGS. 2, 3, and 7, the electrodes 11a4 and 11b4 included in the electrode layer 10d oppose the electrodes 11a1 and 11b1 included in the electrode layer 10a, respectively, with a part of the piezoelectric body 1. The electrodes 12a4 and 12b4 included in the electrode layer 10d oppose the 12a1 and 12b1 included in the electrode layer 10a, respectively, with a part of the piezoelectric body 1. The electrode 11a4 included in the electrode layer 10d opposes the electrode 11a1 included in the electrode layer 10a with the piezoelectric layer. The electrode 11b4 included in the electrode layer 10d opposes the electrode 11b1 included in the electrode layer 10a with the piezoelectric layer. The electrode 12a4 included in the electrode layer 10d opposes the electrode 12a1 included in the electrode layer 10a with the piezoelectric layer. The electrode 12b4 included in the electrode layer 10d opposes the electrode 12b1 included in the electrode layer 10a with the piezoelectric layer. Among the plurality of piezoelectric layers, a piezoelectric layer positioned between the electrode 11a4 of the electrode layer 10d and the electrode 11a1 of the electrode layer 10a, a piezoelectric layer positioned between the electrode 11b4 of the electrode layer 10d and the electrode 11b1 of the electrode layer 10a, a piezoelectric layer positioned between the electrode 12a4 of the electrode layer 10d and the electrode 12a1 of the electrode layer 10a, and a piezoelectric layer positioned between the electrode 12b4 of the electrode layer 10d and the electrode 12b1 of the electrode layer 10a include an active region due to an application of a voltage.

As illustrated in FIGS. 2 and 3, the electrode 11a1 and the electrode 12a1 included in the electrode layer 10a oppose the electrode 12a2 and the electrode 11a2 included in the electrode layer 10b, respectively, with a part of the piezoelectric body 1. The electrode 11b1 and the electrode 12b1 included in the electrode layer 10a oppose the electrode 12b2 and the electrode 11b2 included in the electrode layer 10b, respectively, with a part of the piezoelectric body 1.

The electrode 11a2 and the electrode 12a2 included in the electrode layer 10b oppose the electrode 11a3 and the electrode 12a3 included in the electrode layer 10c, respectively, with a part of the piezoelectric body 1. The electrode 11b2 and the electrode 12b2 included in the electrode layer 10b oppose the electrode 11b3 and the electrode 12b3 included in the electrode layer 10c, respectively, with a part of the piezoelectric body 1.

The electrode 11a3 and the electrode 12a3 included in the electrode layer 10c oppose the electrode 12a4 and the electrode 11a4 included in the electrode layer 10d, respectively, with a part of the piezoelectric body 1. The electrode 11b3 and the electrode 12b3 included in the electrode layer 10c oppose the electrode 12b4 and the electrode 11b4 included in the electrode layer 10d, respectively, with a part of the piezoelectric body 1.

The electrode 11a4 and the electrode 12a4 included in the electrode layer 10d oppose the electrode 11a1 and the electrode 12a1 included in the electrode layer 10a, respectively, with a part of the piezoelectric body 1. The electrode 11b4 and the electrode 12b4 included in the electrode layer 10d oppose the electrode 11b1 and the electrode 12b1 included in the electrode layer 10a, respectively, with a part of the piezoelectric body 1.

As illustrated in FIG. 4, in the electrode layer 10a, the other electrode 11a1 of the pair of electrodes 11a1 and 11b1 and the one electrode 12a1 of the pair of electrodes 12a1 and 12b1 are adjacent to the end surface 1e. The other electrode 12b1 of the pair of electrodes 12a1 and 12b1 and the one electrode 11b1 of the pair of electrodes 11a1 and 11b1 are adjacent to the end surface 1f.

The electrode 11a1 includes a pair of end edges 11c1 and 11d1 opposing each other in the third direction D3. The end edge 11c1 is, for example, closer to the end surface 1e than the end edge 11d1. The electrode 11b1 includes a pair of end edges 11e1 and 11f1 opposing each other in the third direction D3. The end edge 11e1 is, for example, closer to the end surface 1f than the end edge 11f1. The electrode 12a1 includes a pair of end edges 12c1 and 12d1 opposing each other in the third direction D3. The end edge 12c1 is, for example, closer to the end surface 1e than the end edge 12d1. The electrode 12b1 includes a pair of end edges 12e1 and 12f1 opposing each other in the third direction D3. The end edge 12e1 is, for example, closer to the end surface 1f than the end edge 12f1. For example, when the end edges 11c1 and 11d1 include a pair of first end edges, the end edges 12c1 and 12d1 include a pair of second end edges. For example, when the end edges 11e1 and 11f1 include a pair of first end edges, the end edges 12e1 and 12f1 include a pair of second end edges.

As illustrated in FIG. 5, in the electrode layer 10b, one electrode 12a2 of the pair of electrodes 12a2 and 12b2 and the other electrode 11a2 of the pair of electrodes 11a2 and 11b2 are adjacent to the end surface 1e. One electrode 11b2 of the pair of electrodes 11a2 and 11b2 and the other electrode 12b2 of the pair of electrodes 12a2 and 12b2 are adjacent to the end surface 1f.

The electrode 11a2 includes a pair of end edges 11c2 and 11d2 opposing each other in the third direction D3. The end edge 11c2 is, for example, closer to the end surface 1e than the end edge 11d2. The electrode 11b2 includes a pair of end edges 11e2 and 11f2 opposing each other in the third direction D3. The end edge 11e2 is, for example, closer to the end surface 1f than the end edge 11f2. The electrode 12a2 includes a pair of end edges 12c2 and 12d2 opposing each other in the third direction D3. The end edge 12c2 is, for example, closer to the end surface 1e than the end edge 12d2. The electrode 12b2 includes a pair of end edges 12e2 and 12f2 opposing each other in the third direction D3. The end edge 12e2 is, for example, closer to the end surface 1f than the end edge 12f2. For example, when the end edges 11c2 and 11d2 include a pair of first end edges, the end edges 12c2 and 12d2 include a pair of second end edges. For example, when the end edges 11e2 and 11f2 include a pair of first end edges, the end edges 12e2 and 12f2 include a pair of second end edges.

As illustrated in FIG. 6, in the electrode layer 10c, one electrode 12a3 of the pair of electrodes 12a3 and 12b3 and the other electrode 11a3 of the pair of electrodes 11a3 and 11b3 are adjacent to the end surface 1e. One electrode 11b3 of the pair of electrodes 11a3 and 11b3 and the other electrode 12b3 of the pair of electrodes 12a3 and 12b3 are adjacent to the end surface 1f.

The electrode 11a3 includes a pair of end edges 11c3 and 11d3 opposing each other in the third direction D3. The end edge 11c3 is, for example, closer to the end surface 1e than the end edge 11d3. The electrode 11b3 includes a pair of end edges 11e3 and 11f3 opposing each other in the third direction D3. The end edge 11e3 is, for example, closer to the end surface 1f than the end edge 11f3. The electrode 12a3 includes a pair of end edges 12c3 and 12d3 opposing each other in the third direction D3. The end edge 12c3 is, for example, closer to the end surface 1e than the end edge 12d3. The electrode 12b3 includes a pair of end edges 12e3 and 12f3 opposing each other in the third direction D3. The end edge 12e3 is, for example, closer to the end surface 1f than the end edge 12f3. For example, when the end edges 11c3 and 11d3 include a pair of first end edges, the end edges 12c3 and 12d3 include a pair of second end edges. For example, when the end edges 11e3 and 11f3 include a pair of first end edges, the end edges 12e3 and 12f3 include a pair of second end edges.

As illustrated in FIG. 7, in the electrode layer 10d, the other electrode 11a4 of the pair of electrodes 11a4 and 11b4 and the one electrode 12a4 of the pair of electrodes 12a4 and 12b4 are adjacent to the end surface 1e. The other electrode 12b4 of the pair of electrodes 12a4 and 12b4 and the one electrode 11b4 of the pair of electrodes 11a4 and 11b4 are adjacent to the end surface 1f.

The electrode 11a4 includes a pair of end edges 11c4 and 11d4 opposing each other in the third direction D3. The end edge 11c4 is, for example, closer to the end surface 1e than the end edge 11d4. The electrode 11b4 includes a pair of end edges 11e4 and 11f4 opposing each other in the third direction D3. The end edge 11e4 is, for example, closer to the end surface 1f than the end edge 11f4. The electrode 12a4 includes a pair of end edges 12c4 and 12d4 opposing each other in the third direction D3. The end edge 12c4 is, for example, closer to the end surface 1e than the end edge 12d4. The electrode 12b4 includes a pair of end edges 12e4 and 12f4 opposing each other in the third direction D3. The end edge 12e4 is, for example, closer to the end surface 1f than the end edge 12f4. For example, when the end edges 11c4 and 11d4 include a pair of first end edges, the end edges 12c4 and 12d4 include a pair of second end edges. For example, when the end edges 11e4 and 11f4 include a pair of first end edges, the end edges 12e4 and 12f4 include a pair of second end edges.

As illustrated in FIGS. 4 to 7, each of the electrode layer 10a, the electrode layer 10b, the electrode layer 10c, and the electrode layer 10d includes a plurality of connection conductors 16a1, 16b1, a plurality of connection conductors 16a2 and 16b2, a plurality of connection conductors 16a3 and 16b3, and a plurality of connection conductors 16a4 and 16b4 exposed at the side surface 1c, respectively. Each of the electrode layer 10a, the electrode layer 10b, the electrode layer 10c, and the electrode layer 10d includes a plurality of connection conductors 17a1 and 17b1, a plurality of connection conductors 17a2, 17b2, a plurality of connection conductors 17a3 and 17b3, a plurality of connection conductors 17a4 and 17b4 exposed at the side surface 1d, respectively.

The electrode layer 10a includes the plurality of connection conductors 16a1 and 16b1 exposed at the side surface 1c and the plurality of connection conductors 17a1 and 17b1 exposed at the side surface 1d. The electrode layer 10b includes the plurality of connection conductors 16a2 and 16b2 exposed at the side surface 1c and the plurality of connection conductors 17a2 and 17b2 exposed at the side surface 1d. The electrode layer 10c includes the plurality of connection conductors 16a3 and 16b3 exposed at the side surface 1c and the plurality of connection conductors 17a3 and 17b3 exposed at the side surface 1d. The electrode layer 10d includes the plurality of connection conductors 16a4 and 16b4 exposed at the side surface 1c and the plurality of connection conductors 17a4 and 17b4 exposed at the side surface 1d. For example, when each of the connection conductors 16a1, 16b1, 16a2, 16b2, 16a3, 16b3, 16a4, and 16b4 includes the first connection conductor, each of the connection conductors 17a1, 17b1, 17a2, 17b2, 17a3, 17b3, 17a4, and 17b4 includes the second connection conductor.

Each of the plurality of the connection conductors 16a1 and 16b1, the connection conductors 16a2 and 16b2, the connection conductors 16a3 and 16b3, and the connection conductors 16a4 and 16b4 is exposed at the side surface 1c at different positions in the third direction D3, for example. Each of the plurality of the connection conductors 17a1 and 17b1, the connection conductors 17a2 and 17b2, the connection conductors 17a3 and 17b3, the connection conductors 17a4 and 17b4 is exposed at the side surface 1d at different positions in the third direction D3.

As illustrated in FIG. 4, in the electrode layer 10a, the connection conductor 16a1 is disposed on the electrode 12a1. The connection conductor 16a1 and the electrode 12a1 are physically and electrically connected to each other. The connection conductor 16b1 is disposed on the electrode 11b1. The connection conductor 16b1 and the electrode 11b1 are physically and electrically connected to each other. The connection conductor 17a1 is disposed on the electrode 11a1. The connection conductor 17a1 and the electrode 11a1 are physically and electrically connected to each other. The connection conductor 17b1 is disposed on the electrode 12b1. The connection conductor 17b1 and the electrode 12b1 are physically and electrically connected to each other.

The connection conductor 16a1 includes a pair of end edges 16c1 and 16d1 opposing each other in the third direction D3. The end edge 16c1 is, for example, closer to the end surface 1e than the end edge 16d1. The connection conductor 16b1 includes a pair of end edges 16e1 and 16f1 opposing each other in the third direction D3. The end edge 16e1 is, for example, closer to the end surface 1f than the end edge 16f1. The connection conductor 17a1 includes a pair of end edges 17c1 and 17d1 opposing each other in the third direction D3. The end edge 17c1 is, for example, closer to the end surface 1e than the end edge 17d1. The connection conductor 17b1 includes a pair of end edges 17e1 and 17f1 opposing each other in the third direction D3. The end edge 17e1 is, for example, closer to the end surface 1f than the end edge 17f1. For example, when the end edges 16c1 and 16d1 include a pair of third end edges, the end edges 17c1 and 17d1 include a pair of fourth end edges. For example, when the end edges 16e1 and 16f1 include a pair of third end edges, the end edges 17e1 and 17f1 include a pair of fourth end edges.

In the electrode 11b1 and the connection conductor 16b1 connected to each other, the positions of the pair of end edges 11e1 and 11f1 in the third direction D3 are different from the positions of the pair of end edges 16e1 and 16f1 in the third direction D3. The position of the end edge 11e1 in the third direction D3 and the position of the end edge 16e1 in the third direction D3 are different from each other. The position of the end edge 11f1 in the third direction D3 and the position of the end edge 16f1 in the third direction D3 are different from each other. The end edge 16e1 is separated from the end edge 11e1 in the third direction D3. The end edge 16f1 is separated from the end edge 11f1 in the third direction D3.

In the present example, a ratio of a distance between the end edge 11e1 and the end edge 11f1 in the third direction D3 to a distance between the end edge 11f1 and the end edge 16f1 in the third direction D3 is, for example, 0 to 0.5 times. A ratio of a distance between the end edge 11e1 and the end edge 11f1 in the third direction D3 to a distance between the end edge 16e1 and the end edge 16f1 in the third direction D3 is, for example, 0.05 to 0.5 times.

In the electrode 12a1 and the connection conductor 16a1 connected to each other, the positions of the pair of end edges 12c1 and 12d1 in the third direction D3 are different from the positions of the pair of end edges 16c1 and 16d1 in the third direction D3. The position of the end edge 12c1 in the third direction D3 and the position of the end edge 16c1 in the third direction D3 are different from each other. The position of the end edge 12d1 in the third direction D3 is different from the position of the end edge 16d1 in the third direction D3. The end edge 16c1 is separated from the end edge 12c1 in the third direction D3. The end edge 16d1 is separated from the end edge 12d1 in the third direction D3.

In the present example, a ratio of a distance between the end edge 12c1 and the end edge 12d1 in the third direction D3 to a distance between the end edge 12d1 and the end edge 16d1 in the third direction D3 is, for example, 0 to 0.5 times. A ratio of a distance between the end edge 12c1 and the end edge 12d1 in the third direction D3 to a distance between the end edge 16c1 and the end edge 16d1 in the third direction D3 is, for example, 0.05 to 0.5 times.

In the electrode 11a1 and the connection conductor 17a1 connected to each other, the positions of the pair of end edges 11c1 and 11d1 in the third direction D3 are different from the positions of the pair of end edges 17c1 and 17d1 in the third direction D3. The position of the end edge 11c1 in the third direction D3 and the position of the end edge 17c1 in the third direction D3 are different from each other. The position of the end edge 11d1 in the third direction D3 is different from the position of the end edge 17d1 in the third direction D3. The end edge 17c1 is separated from the end edge 11c1 in the third direction D3. The end edge 17d1 is separated from the end edge 11d1 in the third direction D3.

In the present example, a ratio of a distance between the end edge 11c1 and the end edge 11d1 in the third direction D3 to a distance between the end edge 11d1 and the end edge 17d1 in the third direction D3 is, for example, 0 to 0.5 times. A ratio of a distance between the end edge 11c1 and the end edge 11d1 in the third direction D3 to a distance between the end edge 17c1 and the end edge 17d1 in the third direction D3 is, for example, 0.05 to 0.5 times.

In the electrode 12b1 and the connection conductor 17b1 connected to each other, the positions of the pair of end edges 12e1 and 12f1 in the third direction D3 are different from the positions of the pair of end edges 17e1 and 17f1 in the third direction D3. The position of the end edge 12e1 in the third direction D3 and the position of the end edge 17e1 in the third direction D3 are different from each other. The position of the end edge 12f1 in the third direction D3 and the position of the end edge 17f1 in the third direction D3 are different from each other. The end edge 17e1 is separated from the end edge 12e1 in the third direction D3. The end edge 17f1 is separated from the end edge 12f1 in the third direction D3.

In the present example, a ratio of a distance between the end edge 12e1 and the end edge 12f1 in the third direction D3 to a distance between the end edge 12f1 and the end edge 17f1 in the third direction D3 is, for example, 0 to 0.5 times. A ratio of a distance between the end edge 12e1 and the end edge 12f1 in the third direction D3 to a distance between the end edge 17e1 and the end edge 17f1 in the third direction D3 is, for example, 0.05 to 0.5 times.

As illustrated in FIG. 5, in the electrode layer 10b, the connection conductor 16a2 is disposed on the electrode 11a2. The connection conductor 16a2 and the electrode 11a2 are physically and electrically connected to each other. The connection conductor 16b2 is disposed on the electrode 12b2. The connection conductor 16b2 and the electrode 12b2 are physically and electrically connected to each other. The connection conductor 17a2 is disposed on the electrode 12a2. The connection conductor 17a2 and the electrode 12a2 are physically and electrically connected to each other. The connection conductor 17b2 is disposed on the electrode 11b2. The connection conductor 17b2 and the electrode 11b2 are physically and electrically connected to each other.

The connection conductor 16a2 includes a pair of end edges 16c2 and 16d2 opposing each other in the third direction D3. The end edge 16c2 is, for example, closer to the end surface 1e than the end edge 16d2. The connection conductor 16b2 includes a pair of end edges 16e2 and 16f2 opposing each other in the third direction D3. The end edge 16e2 is, for example, closer to the end surface 1f than the end edge 16f2. The connection conductor 17a2 includes a pair of end edges 17c2 and 17d2 opposing each other in the third direction D3. The end edge 17c2 is, for example, closer to the end surface 1e than the end edge 17d2. The connection conductor 17b2 includes a pair of end edges 17e2 and 17f2 opposing each other in the third direction D3. The end edge 17e2 is, for example, closer to the end surface 1f than the end edge 17f2. For example, when the end edges 16c2 and 16d2 include a pair of third end edges, the end edges 17c2 and 17d2 include a pair of fourth end edges. For example, when the end edges 16e2 and 16f2 include a pair of third end edges, the end edges 17e2 and 17f2 include a pair of fourth end edges.

In the electrode 11a2 and the connection conductor 16a2 connected to each other, the positions of the pair of end edges 11c2 and 11d2 in the third direction D3 are different from the positions of the pair of end edges 16c2 and 16d2 in the third direction D3. The position of the end edge 11c2 in the third direction D3 and the position of the end edge 16c2 in the third direction D3 are different from each other. The position of the end edge 11d2 in the third direction D3 is different from the position of the end edge 16d2 in the third direction D3. The end edge 16c2 is separated from the end edge 11c2 in the third direction D3. The end edge 16d2 is separated from the end edge 11d2 in the third direction D3.

In the present example, a ratio of a distance between the end edge 11c2 and the end edge 11d2 in the third direction D3 to a distance between the end edge 11c2 and the end edge 16c2 in the third direction D3 is, for example, 0 to 0.5 times. A ratio of a distance between the end edge 11c2 and the end edge 11d2 in the third direction D3 to a distance between the end edge 16c2 and the end edge 16d2 in the third direction D3 is, for example, 0.05 to 0.5 times.

In the electrode 12b2 and the connection conductor 16b2 connected to each other, the positions of the pair of end edges 12e2 and 12f2 in the third direction D3 are different from the positions of the pair of end edges 16e2 and 16f2 in the third direction D3. The position of the end edge 12e2 in the third direction D3 and the position of the end edge 16e2 in the third direction D3 are different from each other. The position of the end edge 12f2 in the third direction D3 is different from the position of the end edge 16f2 in the third direction D3. The end edge 16e2 is separated from the end edge 12e2 in the third direction D3. The end edge 16f2 is separated from the end edge 12f2 in the third direction D3.

In the present example, a ratio of a distance between the end edge 12e2 and the end edge 12f2 in the third direction D3 to a distance between the end edge 12e2 and the end edge 16e2 in the third direction D3 is, for example, 0 to 0.5 times. A ratio of a distance between the end edge 12e2 and the end edge 12f2 in the third direction D3 to a distance between the end edge 16e2 and the end edge 16f2 in the third direction D3 is, for example, 0.05 to 0.5 times.

In the electrode 11b2 and the connection conductor 17b2 connected to each other, the positions of the pair of end edges 11e2 and 11f2 in the third direction D3 are different from the positions of the pair of end edges 17e2 and 17f2 in the third direction D3. The position of the end edge 11e2 in the third direction D3 and the position of the end edge 17e2 in the third direction D3 are different from each other. The position of the end edge 11f2 in the third direction D3 is different from the position of the end edge 17f2 in the third direction D3. The end edge 17e2 is separated from the end edge 11e2 in the third direction D3. The end edge 17f2 is separated from the end edge 11f2 in the third direction D3.

In the present example, a ratio of a distance between the end edge 11e2 and the end edge 11f2 in the third direction D3 to a distance between the end edge 11e2 and the end edge 17e2 in the third direction D3 is, for example, 0 to 0.5 times. A ratio of a distance between the end edge 11e2 and the end edge 11f2 in the third direction D3 to a distance between the end edge 17e2 and the end edge 17f2 in the third direction D3 is, for example, 0.05 to 0.5 times.

In the electrode 12a2 and the connection conductor 17a2 connected to each other, the positions of the pair of end edges 12c2 and 12d2 in the third direction D3 are different from the positions of the pair of end edges 17c2 and 17d2 in the third direction D3. The position of the end edge 12c2 in the third direction D3 is different from the position of the end edge 17c2 in the third direction D3. The position of the end edge 12d2 in the third direction D3 is different from the position of the end edge 17d2 in the third direction D3. The end edge 17c2 is separated from the end edge 12c2 in the third direction D3. The end edge 17d2 is separated from the end edge 12d2 in the third direction D3.

In the present example, a ratio of a distance between the end edge 12c2 and the end edge 12d2 in the third direction D3 to a distance between the end edge 12c2 and the end edge 17c2 in the third direction D3 is, for example, 0 to 0.5 times. A ratio of a distance between the end edge 12c2 and the end edge 12d2 in the third direction D3 to a distance between the end edge 17c2 and the end edge 17d2 in the third direction D3 is, for example, 0.05 to 0.5 times.

As illustrated in FIG. 6, in the electrode layer 10c, the connection conductor 16a3 is disposed on the electrode 11a3. The connection conductor 16a3 and the electrode 11a3 are physically and electrically connected to each other. The connection conductor 16b3 is disposed on the electrode 12b3. The connection conductor 16b3 and the electrode 12b3 are physically and electrically connected to each other. The connection conductor 17a3 is disposed on the electrode 12a3. The connection conductor 17a3 and the electrode 12a3 are physically and electrically connected to each other. The connection conductor 17b3 is disposed on the electrode 11b3. The connection conductor 17b3 and the electrode 11b3 are physically and electrically connected to each other.

The connection conductor 16a3 includes a pair of end edges 16c3 and 16d3 opposing each other in the third direction D3. The end edge 16c3 is, for example, closer to the end surface 1e than the end edge 16d3. The connection conductor 16b3 includes a pair of end edges 16e3 and 16f3 opposing each other in the third direction D3. The end edge 16e3 is, for example, closer to the end surface 1f than the end edge 16f3. The connection conductor 17a3 includes a pair of end edges 17c3 and 17d3 opposing each other in the third direction D3. The end edge 17c3 is, for example, closer to the end surface 1e than the end edge 17d3. The connection conductor 17b3 includes a pair of end edges 17e3 and 17f3 opposing each other in the third direction D3. The end edge 17e3 is, for example, closer to the end surface 1f than the end edge 17f3. For example, when the end edges 16c3 and 16d3 include a pair of third end edges, the end edges 17c3 and 17d3 include a pair of fourth end edges. For example, when the end edges 16e3 and 16f3 include a pair of third end edges, the end edges 17e3 and 17f3 include a pair of fourth end edges.

In the electrode 11a3 and the connection conductor 16a3 connected to each other, the positions of the pair of end edges 11c3 and 11d3 in the third direction D3 are different from the positions of the pair of end edges 16c3 and 16d3 in the third direction D3. The position of the end edge 11c3 in the third direction D3 and the position of the end edge 16c3 in the third direction D3 are different from each other. The position of the end edge 11d3 in the third direction D3 is different from the position of the end edge 16d3 in the third direction D3. The end edge 16c3 is separated from the end edge 11c3 in the third direction D3. The end edge 16d3 is separated from the end edge 11d3 in the third direction D3.

In the present example, a ratio of a distance between the end edge 11c3 and the end edge 11d3 in the third direction D3 to a distance between the end edge 11d3 and the end edge 16d3 in the third direction D3 is, for example, 0 to 0.5 times. A ratio of a distance between the end edge 11c3 and the end edge 11d3 in the third direction D3 to a distance between the end edge 16c3 and the end edge 16d3 in the third direction D3 is, for example, 0.05 to 0.5 times.

In the electrode 12b3 and the connection conductor 16b3 connected to each other, the positions of the pair of end edges 12e3 and 12f3 in the third direction D3 are different from the positions of the pair of end edges 16e3 and 16f3 in the third direction D3. The position of the end edge 12e3 in the third direction D3 and the position of the end edge 16e3 in the third direction D3 are different from each other. The position of the end edge 12f3 in the third direction D3 is different from the position of the end edge 16f3 in the third direction D3. The end edge 16e3 is separated from the end edge 12e3 in the third direction D3. The end edge 16f3 is separated from the end edge 12f3 in the third direction D3.

In the present example, a ratio of a distance between the end edge 12e3 and the end edge 12f3 in the third direction D3 to a distance between the end edge 12e3 and the end edge 16f3 in the third direction D3 is, for example, 0 to 0.5 times. A ratio of a distance between the end edge 12e3 and the end edge 12f3 in the third direction D3 to a distance between the end edge 16e3 and the end edge 16f3 in the third direction D3 is, for example, 0.05 to 0.5 times.

In the electrode 11b3 and the connection conductor 17b3 connected to each other, the positions of the pair of end edges 11e3 and 11f3 in the third direction D3 are different from the positions of the pair of end edges 17e3 and 17f3 in the third direction D3. The position of the end edge 11e3 in the third direction D3 and the position of the end edge 17e3 in the third direction D3 are different from each other. The position of the end edge 11f3 in the third direction D3 is different from the position of the end edge 17f3 in the third direction D3. The end edge 17e3 is separated from the end edge 11e3 in the third direction D3. The end edge 17f3 is separated from the end edge 11f3 in the third direction D3.

In the present example, a ratio of a distance between the end edge 11e3 and the end edge 11f3 in the third direction D3 to a distance between the end edge 11f3 and the end edge 1713 in the third direction D3 is, for example, 0 to 0.5 times. A ratio of a distance between the end edge 11e3 and the end edge 11f3 in the third direction D3 to a distance between the end edge 17e3 and the end edge 17f3 in the third direction D3 is, for example, 0.05 to 0.5 times.

In the electrode 12a3 and the connection conductor 17a3 connected to each other, the positions of the pair of end edges 12c3 and 12d3 in the third direction D3 are different from the positions of the pair of end edges 17c3 and 17d3 in the third direction D3. The position of the end edge 12c3 in the third direction D3 and the position of the end edge 17c3 in the third direction D3 are different from each other. The position of the end edge 12d3 in the third direction D3 and the position of the end edge 17d3 in the third direction D3 are different from each other. The end edge 17c3 is separated from the end edge 12c3 in the third direction D3. The end edge 17d3 is separated from the end edge 12d3 in the third direction D3.

In the present example, a ratio of a distance between the end edge 12c3 and the end edge 12d3 in the third direction D3 to a distance between the end edge 12d3 and the end edge 17d3 in the third direction D3 is, for example, 0 to 0.5 times. A ratio of a distance between the end edge 12c3 and the end edge 12d3 in the third direction D3 to a distance between the end edge 17c3 and the end edge 17d3 in the third direction D3 is, for example, 0.05 to 0.5 times.

As illustrated in FIG. 7, in the electrode layer 10d, the connection conductor 16a4 is disposed on the electrode 12a4. The connection conductor 16a4 and the electrode 12a4 are physically and electrically connected to each other. The connection conductor 16b4 is disposed on the electrode 11b4. The connection conductor 16b4 and the electrode 11b4 are physically and electrically connected to each other. The connection conductor 17a4 is disposed on the electrode 11a4. The connection conductor 17a4 and the electrode 11a4 are physically and electrically connected to each other. The connection conductor 17b4 is disposed on the electrode 12b4. The connection conductor 17b4 and the electrode 12b4 are physically and electrically connected to each other.

The connection conductor 16a4 includes a pair of end edges 16c4 and 16d4 opposing each other in the third direction D3. The end edge 16c4 is, for example, closer to the end surface 1e than the end edge 16d4. The connection conductor 16b4 includes a pair of end edges 16e4 and 16f4 opposing each other in the third direction D3. The end edge 16e4 is, for example, closer to the end surface 1f than the end edge 16f4. The connection conductor 17a4 includes a pair of end edges 17c4 and 17d4 opposing each other in the third direction D3. The end edge 17c4 is, for example, closer to the end surface 1e than the end edge 17d4. The connection conductor 17b4 includes a pair of end edges 17e4 and 17f4 opposing each other in the third direction D3. The end edge 17e4 is, for example, closer to the end surface 1f than the end edge 17f4. For example, when the end edges 16c4 and 16d4 include a pair of third end edges, the end edges 17c4 and 17d4 include a pair of fourth end edges. For example, when the end edges 16e4 and 16f4 include a pair of third end edges, the end edges 17e4 and 17f4 include a pair of fourth end edges.

In the electrode 11b4 and the connection conductor 16b4 connected to each other, the positions of the pair of end edges 11e4 and 11f4 in the third direction D3 are different from the positions of the pair of end edges 16e4 and 16f4 in the third direction D3. The position of the end edge 11e4 in the third direction D3 and the position of the end edge 16e4 in the third direction D3 are different from each other. The position of the end edge 11f4 in the third direction D3 is different from the position of the end edge 16f4 in the third direction D3. The end edge 16e4 is separated from the end edge 11e4 in the third direction D3. The end edge 16f4 is separated from the end edge 11f4 in the third direction D3.

In the present example, a ratio of a distance between the end edge 11e4 and the end edge 11f4 in the third direction D3 to a distance between the end edge 11e4 and the end edge 16e4 in the third direction D3 is, for example, 0 to 0.5 times. A ratio of a distance between the end edge 11e4 and the end edge 11f4 in the third direction D3 to a distance between the end edge 16e4 and the end edge 16f4 in the third direction D3 is, for example, 0.05 to 0.5 times.

In the electrode 12a4 and the connection conductor 16a4 connected to each other, the positions of the pair of end edges 12c4 and 12d4 in the third direction D3 are different from the positions of the pair of end edges 16c4 and 16d4 in the third direction D3. The position of the end edge 12c4 in the third direction D3 and the position of the end edge 16c4 in the third direction D3 are different from each other. The position of the end edge 12d4 in the third direction D3 is different from the position of the end edge 16d4 in the third direction D3. The end edge 16c4 is separated from the end edge 12c4 in the third direction D3. The end edge 16d4 is separated from the end edge 12d4 in the third direction D3.

In the present example, a ratio of a distance between the end edge 12c4 and the end edge 12d4 in the third direction D3 to a distance between the end edge 12c4 and the end edge 16c4 in the third direction D3 is, for example, 0 to 0.5 times. A ratio of a distance between the end edge 12c4 and the end edge 12d4 in the third direction D3 to a distance between the end edge 16c4 and the end edge 16d4 in the third direction D3 is, for example, 0.05 to 0.5 times.

In the electrode 11a4 and the connection conductor 17a4 connected to each other, the positions of the pair of end edges 11c4 and 11d4 in the third direction D3 are different from the positions of the pair of end edges 17c4 and 17d4 in the third direction D3. The position of the end edge 11c4 in the third direction D3 and the position of the end edge 17c4 in the third direction D3 are different from each other. The position of the end edge 11d4 in the third direction D3 is different from the position of the end edge 17d4 in the third direction D3. The end edge 17c4 is separated from the end edge 11c4 in the third direction D3. The end edge 17d4 is separated from the end edge 11d4 in the third direction D3.

In the present example, a ratio of a distance between the end edge 11c4 and the end edge 11d4 in the third direction D3 to a distance between the end edge 11c4 and the end edge 17c4 in the third direction D3 is, for example, 0 to 0.5 times. A ratio of a distance between the end edge 11c4 and the end edge 11d4 in the third direction D3 to a distance between the end edge 17c4 and the end edge 17d4 in the third direction D3 is, for example, 0.05 to 0.5 times.

In the electrode 12b4 and the connection conductor 17b4 connected to each other, the positions of the pair of end edges 12e4 and 12f4 in the third direction D3 are different from the positions of the pair of end edges 17e4 and 17f4 in the third direction D3. The position of the end edge 12e4 in the third direction D3 and the position of the end edge 17e4 in the third direction D3 are different from each other. The position of the end edge 12f4 in the third direction D3 is different from the position of the end edge 17f4 in the third direction D3. The end edge 17e4 is separated from the end edge 12e4 in the third direction D3. The end edge 17f4 is separated from the end edge 12f4 in the third direction D3.

In the present example, a ratio of a distance between the end edge 12e4 and the end edge 12f4 in the third direction D3 to a distance between the end edge 12e4 and the end edge 17e4 in the third direction D3 is, for example, 0 to 0.5 times. A ratio of a distance between the end edge 12e4 and the end edge 12f4 in the third direction D3 to a distance between the end edge 17e4 and the end edge 17f4 in the third direction D3 is, for example, 0.05 to 0.5 times.

In the present example, a first shortest distance L1 between the connection conductor 16a1 connected to one electrode 12a1 of the pair of electrodes 12a1 and 12b1 and the connection conductor 17b1 connected to the other electrode 12b1 of the pair of electrodes 12a1 and 12b1 in the electrode layer 10a is different from a second shortest distance L2 between the connection conductor 17a2 connected to one electrode 12a2 of the pair of electrodes 12a2 and 12b2 and the connection conductor 16b2 connected to the other electrode 12b2 of the pair of electrodes 12a2 and 12b2 in the electrode layer 10b.

In the present example, a first shortest distance L1 between the connection conductor 17a3 connected to one electrode 12a3 of the pair of electrodes 12a3 and 12b3 and the connection conductor 16b3 connected to the other electrode 12b3 of the pair of electrodes 12a3 and 12b3 in the electrode layer 10c is different from a second shortest distance L2 between the connection conductor 17a2 connected to one electrode 12a2 of the pair of electrodes 12a2 and 12b2 and the connection conductor 16b2 connected to the other electrode 12b2 of the pair of electrodes 12a2 and 12b2 in the electrode layer 10b.

In the present example, a first shortest distance L1 between the connection conductor 17a3 connected to one electrode 12a3 of the pair of electrodes 12a3 and 12b3 and the connection conductor 16b3 connected to the other electrode 12b3 of the pair of electrodes 12a3 and 12b3 in the electrode layer 10c is different from a second shortest distance L2 between the connection conductor 16a4 connected to one electrode 12a4 of the pair of electrodes 12a4 and 12b4 and the connection conductor 17b4 connected to the other electrode 12b4 of the pair of electrodes 12a4 and 12b4 in the electrode layer 10d.

In the present example, a first shortest distance L1 between the connection conductor 16a1 connected to one electrode 12a1 of the pair of electrodes 12a1 and 12b1 and the connection conductor 17b1 connected to the other electrode 12b1 of the pair of electrodes 12a1 and 12b1 in the electrode layer 10a is different from a second shortest distance L2 between the connection conductor 16a4 connected to one electrode 12a4 of the pair of electrodes 12a4 and 12b4 and the connection conductor 17b4 connected to the other electrode 12b4 of the pair of electrodes 12a4 and 12b4 in the electrode layer 10d.

In the present example, the first shortest distance L1 is smaller than the second shortest distance L2. The first shortest distance L1 is, for example, 0.2 to 0.6 times the second shortest distance L2.

In the present example, a third shortest distance L3 between the connection conductor 17a1 connected to one electrode 11a1 of the pair of electrodes 11a1 and 11b1 and the connection conductor 16b1 connected to the other electrode 11b1 of the pair of electrodes 11a1 and 11b1 in the electrode layer 10a is different from a fourth shortest distance L4 between the connection conductor 16a2 connected to one electrode 11a2 of the pair of electrodes 11a2 and 11b2 and the connection conductor 17b2 connected to the other electrode 11b2 of the pair of electrodes 11a2 and 11b2 in the electrode layer 10b.

In the present example, a third shortest distance L3 between the connection conductor 16a3 connected to one electrode 11a3 of the pair of electrodes 11a3 and 11b3 and the connection conductor 17b3 connected to the other electrode 11b3 of the pair of electrodes 11a3 and 11b3 in the electrode layer 10c is different from a fourth shortest distance L4 between the connection conductor 16a2 connected to one electrode 11a2 of the pair of electrodes 11a2 and 11b2 and the connection conductor 17b2 connected to the other electrode 11b2 of the pair of electrodes 11a2 and 11b2 in the electrode layer 10b.

In the present example, a third shortest distance L3 between the connection conductor 16a3 connected to one electrode 11a3 of the pair of electrodes 11a3 and 11b3 and the connection conductor 17b3 connected to the other electrode 11b3 of the pair of electrodes 11a3 and 11b3 in the electrode layer 10c is different from a fourth shortest distance L4 between the connection conductor 17a4 connected to one electrode 11a4 of the pair of electrodes 11a4 and 11b4 and the connection conductor 16b4 connected to the other electrode 11b4 of the pair of electrodes 11a4 and 11b4 in the electrode layer 10d.

In the present example, a third shortest distance L3 between the connection conductor 17a1 connected to one electrode 11a1 of the pair of electrodes 11a1 and 11b1 and the connection conductor 16b1 connected to the other electrode 11b1 of the pair of electrodes 11a1 and 11b1 in the electrode layer 10a is different from a fourth shortest distance L4 between the connection conductor 17a4 connected to one electrode 11a4 of the pair of electrodes 11a4 and 11b4 and the connection conductor 16b4 connected to the other electrode 11b4 of the pair of electrodes 11a4 and 11b4 in the electrode layer 10d.

In the present example, the third shortest distance L3 is smaller than the fourth shortest distance L4. The third shortest distance L3 is, for example, 0.2 to 0.6 times the fourth shortest distance L4.

The electrode layer 10 includes, for example, an electrically conductive material. The electrically conductive material included in the electrode layer 10 includes, for example, Ag, Pd, Au, Ni, Pt, or Cu. The electrically conductive material may include, for example, an Ag—Pd alloy, an Ag—Cu alloy, an Ag—Au alloy, or an Ag—Pt alloy. The electrode layer 10 includes a sintered body of an electrically conductive paste containing the electrically conductive material. A thickness of the electrode layer 10 is, for example, 0.5 to 5 μm.

As illustrated in FIG. 1, the external electrode 20 includes a plurality of external electrodes 20a, 20b, 20c, and 20d and a plurality of external electrodes 20e, 20f, 20g, and 20h. In the present example, the external electrode 20 includes four external electrodes 20a, 20b, 20c, and 20d and four external electrodes 20e, 20f, 20g, and 20h.

The external electrodes 20a, 20b, 20c, and 20d are disposed on the side surface 1c. For example, the external electrode 20a, the external electrode 20b, the external electrode 20c, and the external electrode 20d are positioned in the order of the external electrode 20a, the external electrode 20b, the external electrode 20c, and the external electrode 20d in a direction from the end surface 1e toward the end surface 1f in the third direction D3.

The external electrodes 20e, 20f, 20g, and 20h are disposed on the side surface 1d. The external electrode 20e, the external electrode 20f, the external electrode 20g, and the external electrode 20h are positioned in the order of the external electrode 20e, the external electrode 20f, the external electrode 20g, and the external electrode 20h, for example, in a direction from the end surface 1e toward the end surface 1f in the third direction D3.

For example, when the external electrode 20a includes a first external electrode, the external electrode 20b includes a second external electrode, the external electrode 20c includes a third external electrode, and the external electrode 20d includes a fourth external electrode. For example, when the external electrode 20a includes a first external electrode, the external electrode 20e includes a fifth external electrode, the external electrode 20f includes a sixth external electrode, the external electrode 20g includes a seventh external electrode, and the external electrode 20h includes an eighth external electrode.

As illustrated in FIGS. 5 and 7, the external electrode 20a is connected to the connection conductor 16a2 and the connection conductor 16a4. The connection conductor 16a2 is connected to one electrode 11a2 of the pair of electrodes 11a2 and 11b2 included in the electrode layer 10b. The connection conductor 16a4 is connected to one electrode 12a4 of the pair of electrodes 12a4 and 12b4 included in the electrode layer 10d. In the present example, the external electrode 20a is connected to the electrode 11a2 included in the electrode layer 10b disposed in the electrode layer groups EG1 and EG2 and the electrode 12a4 included in the electrode layer 10d disposed in the electrode layer groups EG1 and EG2.

As illustrated in FIGS. 4 and 6, the external electrode 20b is connected to the connection conductor 16a1 and the connection conductor 16a3. The connection conductor 16a1 is connected to one electrode 12a1 of the pair of electrodes 12a1 and 12b1 included in the electrode layer 10a. The connection conductor 16a3 is connected to one electrode 11a3 of the pair of electrodes 11a3 and 11b3 included in the electrode layer 10c. In the present example, the external electrode 20b is connected to the electrode 12a1 included in the electrode layer 10a disposed in the electrode layer groups EG1, EG2, and EG3 and the electrode 11a3 included in the electrode layer 10c disposed in the electrode layer groups EG1 and EG2.

As illustrated in FIGS. 4 and 6, the external electrode 20c is connected to the connection conductor 16b1 and the connection conductor 16b3. The connection conductor 16b1 is connected to one electrode 11b1 of the pair of electrodes 11a1 and 11b1 included in the electrode layer 10a. The connection conductor 16b3 is connected to one electrode 12b3 of the pair of electrodes 12a3 and 12b3 included in the electrode layer 10c. In the present example, the external electrode 20c is connected to the electrode 11b1 included in the electrode layer 10a disposed in the electrode layer groups EG1, EG2, and EG3 and the electrode 12b3 included in the electrode layer 10c disposed in the electrode layer groups EG1 and EG2.

As illustrated in FIGS. 5 and 7, the external electrode 20d is connected to the connection conductor 16b2 and the connection conductor 16b4. The connection conductor 16b2 is connected to one electrode 12b2 of the pair of electrodes 12a2 and 12b2 included in the electrode layer 10b. The connection conductor 16b4 is connected to one electrode 11b4 of the pair of electrodes 11a4 and 11b4 included in the electrode layer 10d. In the present example, the external electrode 20d is connected to the electrode 12b2 included in the electrode layer 10b disposed in the electrode layer groups EG1 and EG2 and the electrode 11b4 included in the electrode layer 10d disposed in the electrode layer groups EG1 and EG2.

As illustrated in FIGS. 5 and 7, the external electrode 20e is connected to the connection conductor 17a2 and the connection conductor 17a4. The connection conductor 17a2 is connected to the other electrode 12a2 of the pair of electrodes 12a2 and 12b2 included in the electrode layer 10b. The connection conductor 17a4 is connected to the other electrode 11a4 of the pair of electrodes 11a4 and 11b4 included in the electrode layer 10d. In the present example, the external electrode 20e is connected to the electrode 12a2 included in the electrode layer 10b disposed in the electrode layer groups EG1 and EG2 and the electrode 11a4 included in the electrode layer 10d disposed in the electrode layer groups EG1 and EG2.

As illustrated in FIGS. 4 and 6, the external electrode 20f is connected to the connection conductor 17a1 and the connection conductor 17a3. The connection conductor 17a1 is connected to the other electrode 11a1 of the pair of electrodes 11a1 and 11b1 included in the electrode layer 10a. The connection conductor 17a3 is connected to the other electrode 12a3 of the pair of electrodes 12a3 and 12b3 included in the electrode layer 10c. In the present example, the external electrode 20f is connected to the electrode 11a1 included in the electrode layer 10a disposed in the electrode layer groups EG1, EG2, and EG3 and the electrode 12a3 included in the electrode layer 10c disposed in the electrode layer groups EG1 and EG2.

As illustrated in FIGS. 4 and 6, the external electrode 20g is connected to the connection conductor 17b1 and the connection conductor 17b3. The connection conductor 17b1 is connected to the other electrode 12b1 of the pair of electrodes 12a1 and 12b1 included in the electrode layer 10a. The connection conductor 17b3 is connected to the other electrode 11b3 of the pair of electrodes 11a3 and 11b3 included in the electrode layer 10c. In the present example, the external electrode 20g is connected to the electrode 12b1 included in the electrode layer 10a disposed in the electrode layer groups EG1, EG2, and EG3 and the electrode 11b3 included in the electrode layer 10c disposed in the electrode layer groups EG1 and EG2.

As illustrated in FIGS. 5 and 7, the external electrode 20h is connected to the connection conductor 17b2 and the connection conductor 17b4. The connection conductor 17b2 is connected to the other electrode 11b2 of the pair of electrodes 11a2 and 11b2 included in the electrode layer 10b. The connection conductor 17b4 is connected to the other electrode 12b4 of the pair of electrodes 12a4 and 12b4 included in the electrode layer 10d. In the present example, the external electrode 20h is connected to the electrode 11b2 included in the electrode layer 10b disposed in the electrode layer groups EG1 and EG2 and the electrode 12b4 included in the electrode layer 10d disposed in the electrode layer groups EG1 and EG2.

The external electrode 20 includes, for example, a sintered metal layer. The sintered metal layer is formed due to sintering the electrically conductive paste applied to the side surfaces 1c and 1d. The external electrode 20 is formed, for example, due to sintering a metal powder contained in the electrically conductive paste. The sintered metal layer contains an electrically conductive material of a noble metal or a noble metal alloy. The noble metal includes, for example, Ag, Pd, Au, or Pt. The noble metal alloy includes, for example, an Ag—Pd alloy. The external electrode 20 may include a plated layer disposed on the sintered metal layer. The plated layer includes, for example, a Ni plated layer, a Sn plated layer, a Cu plated layer, an Au plated layer, a Sn—Ag alloy plated layer, a Sn—Bi alloy plated layer, or a Sn—Cu alloy plated layer. A thickness of the external electrode 20 is, for example, 0.5 to 5 μm.

The piezoelectric element PD1 includes, for example, electrically conductive lines 30a and 30b. As illustrated in FIG. 8, the electrically conductive line 30a is disposed on the side surface 1c, for example. As illustrated in FIG. 9, the electrically conductive line 30b is, for example, disposed on the side surface 1c.

FIG. 8 illustrates the electrically conductive line 30a. The electrically conductive line 30a includes a plurality of electrical conductors 31a, 31b, 31c, and 31d and a plurality of electrical lines 32a, 32b, 32c, and 32d. In the present example, the electrically conductive line 30a includes four conductors 31a, 31b, 31c, and 31d and four electrical lines 32a, 32b, 32c, and 32d. The electrically conductive line 30a extends, for example, in the third direction D3 on the side surface 1c.

The plurality of conductors 31a, 31b, 31c, and 31d is electrically connected to any one of the plurality of external electrodes 20a, 20b, 20c, and 20d, respectively. The conductor 31a is electrically connected to the external electrode 20a, for example. The conductor 31b is electrically connected to the external electrode 20b, for example. The conductor 31c is electrically connected to the external electrode 20c, for example. The conductor 31d is electrically connected to the external electrode 20d, for example. For example, the plurality of conductors 31a, 31b, 31c, and 31d are positioned in the order of the conductor 31a, the conductor 31b, the conductor 31c, and the conductor 31d in a direction from the end surface 1e toward the end surface 1f in the third direction D3.

The plurality of electrical lines 32a, 32b, 32c, and 32d are electrically connected to any one of the plurality of conductors 31a, 31b, 31c, and 31d, respectively. The electrical line 32a is electrically connected to the conductor 31a, for example. The electrical line 32b is electrically connected to the conductor 31b, for example. The electrical line 32c is electrically connected to the conductor 31c, for example. The electrical line 32d is electrically connected to the conductor 31d, for example. The electrical line 32b is closer to the main surface 1b than the electrical line 32a. The electrical lines 32c and 32d extend in a region near the main surface 1a. The electrical line 32d is closer to the main surface 1a than the electrical line 32c.

The electrically conductive line 30a includes, for example, a region E1a, a region E2a, and a region E3a. For example, the region E1a is located between the region E2a and the region E3a in the first direction D1. The region E2a is located closer to the main surface 1b. The region E3a is located closer to the main surface 1a.

In the region E1a, for example, the conductors 31a, 31b, 31c, and 31d are disposed. In the region E2a, for example, the electrical lines 32a and 32b are disposed. In the region E3a, for example, the electrical lines 32c and 32d are disposed. In the region E2a, the electrical line 32a is covered with a covering member not to be electrically connected to the external electrodes 20b, 20c, and 20d. In the region E2a, the electrical line 32b is covered with a covering member not to be electrically connected to the external electrodes 20a, 20c, and 20d. In the region E3a, the electrical line 32c is covered with a covering member not to be electrically connected to the external electrodes 20a, 20b, and 20d. In the region E3a, the electrical line 32d is covered with a covering member not to be electrically connected to the external electrodes 20a, 20b, and 20c. In the region E1a, the conductors 31a, 31b, 31c, and 31d may not be covered with the covering member.

The covering member covering the electrical line 32a is disposed, for example, between the electrical line 32a and the external electrodes 20b, 20c, and 20d. The covering member that covers the electrical line 32b is disposed, for example, between the electrical line 32b and the external electrodes 20a, 20c, and 20d. The covering member covering the electrical line 32c is disposed, for example, between the electrical line 32c and the external electrodes 20a, 20b, and 20d. The covering member covering the electrical line 32d is disposed, for example, between the electrical line 32d and the external electrodes 20a, 20b, and 20c.

The electrically conductive line 30a includes, for example, a flexible printed circuit board (FPC) or a lead frame. The electrical lines 32a, 32b, 32c, and 32d and the external electrodes 20a, 20b, 20c, and 20d are disposed on the board, for example. In the present example, another electrically conductive line having the same form as the electrically conductive line 30a is disposed on the side surface 1d. The other electrically conductive line is electrically connected to the external electrodes 20e, 20f, 20g, and 20h.

FIG. 9 illustrates an example of another electrically conductive line 30b. The electrically conductive line 30b includes a plurality of conductors 31a, 31b, 31c, and 31d and a plurality of electrical lines 32a, 32b, 32c, and 32d. In the present example, the electrically conductive line 30b includes four conductors 31a, 31b, 31c, and 31d and four electrical lines 32a, 32b, 32c, and 32d. The plurality of conductors 31a, 31b, 31c, and 31d is electrically connected to any one of the external electrodes 20a, 20b, 20c, and 20d. The conductor 31a is electrically connected to the external electrode 20a, for example. The conductor 31b is electrically connected to the external electrode 20b, for example. The conductor 31c is electrically connected to the external electrode 20c, for example. The conductor 31d is electrically connected to the external electrode 20d, for example.

The plurality of electrical lines 32a, 32b, 32c, and 32d are electrically connected to any of the conductors 31a, 31b, 31c, and 31d. The electrical line 32a is electrically connected to the conductor 31a, for example. The electrical line 32b is electrically connected to the conductor 31b, for example. The electrical line 32c is electrically connected to the conductor 31c, for example. The electrical line 32d is electrically connected to the conductor 31d, for example.

The electrically conductive line 30b includes, for example, a portion P1a, a portion P2a, and a portion P3a. In the portion P1a, for example, the plurality of conductors 31a, 31b, 31c, and 31d are positioned in the order of the conductor 31a, the conductor 31b, the conductor 31c, and the conductor 31d in a direction from the end surface 1e toward the end surface 1f in the third direction D3. In the portion P2a, the plurality of electrical lines 32a, 32b, 32c, and 32d extend, for example, in a direction intersecting the first direction D1 and the third direction D3. In the portion P3a, the plurality of electrical lines 32a, 32b, 32c, and 32d extend, for example, in the first direction D1.

In the portion P2a, the electrical lines 32a, 32b, 32c, and 32d are covered with a covering member not to be electrically connected to the plurality of external electrodes 20a, 20b, 20c, and 20d. The electrical line 32a is covered with the covering member not to be electrically connected to the plurality of external electrodes 20b, 20c, and 20d. The electrical line 32b is covered with a covering member not to be electrically connected to the plurality of external electrodes 20a, 20c, and 20d. The electrical line 32c is covered with a covering member not to be electrically connected to the plurality of external electrodes 20a, 20b, and 20d. The electrical line 32d is covered with a covering member not to be electrically connected to the plurality of external electrodes 20a, 20b, and 20c.

The covering member covering the electrical line 32a is disposed, for example, between the electrical line 32a and the external electrodes 20b, 20c, and 20d. The covering member that covers the electrical line 32b is disposed, for example, between the electrical line 32b and the external electrodes 20a, 20c, and 20d. The covering member covering the electrical line 32c is disposed, for example, between the electrical line 32c and the external electrodes 20a, 20b, and 20d. The covering member covering the electrical line 32d is disposed, for example, between the electrical line 32d and the external electrodes 20a, 20b, and 20c. The plurality of conductors 31a, 31b, 31c, and 31d may not be covered with the covering member. In the portion P3a, the electrical lines 32a, 32b, 32c, and 32d may not be covered with the covering member.

The electrically conductive line 30b includes, for example, a flexible printed circuit board (FPC) or a lead frame. The electrical lines 32a, 32b, 32c, and 32d and the external electrodes 20a, 20b, 20c, and 20d are disposed on the board, for example. In the present example, another electrically conductive line having the same form as the electrically conductive line 30b is disposed on the side surface 1d. Another electrically conductive line is electrically connected to the external electrodes 20e, 20f, 20g, and 20h.

As described above, in the piezoelectric element PD1, when the active region is formed between the electrode layer 10a and the electrode layer 10b, the magnitude of the electric potential applied to the pair of electrodes 11a1 and 11b1 may be different from the magnitude of the electric potential applied to the pair of electrodes 12a1 and 12b1. The magnitude of the electric potential applied to the pair of electrodes 11a2 and 11b2 may be different from the magnitude of the electric potential applied to the pair of electrodes 12a2 and 12b2.

The piezoelectric element PD1 increases the degree of freedom of the magnitude of the electric potential applied to the pair of electrodes 11a2 and 11b2 and the pair of electrodes 12a2 and 12b2, as compared with a configuration in which the electrode layer 10a includes a plurality of electrodes and the electrode layer 10b includes one electrode.

In the piezoelectric element PD1, when the active region is formed between the electrode layer 10b and the electrode layer 10c, the magnitude of the electric potential applied to the pair of electrodes 11a3 and 11b3 may be different from the magnitude of the electric potential applied to the pair of electrodes 12a3 and 12b3.

The piezoelectric element PD1 increases the degree of freedom of the magnitude of the electric potential applied to the pair of electrodes 11a3 and 11b3 and the pair of electrodes 12a3 and 12b3, as compared with a configuration in which the electrode layer 10b includes a plurality of electrodes and the electrode layer 10c includes one electrode.

In the piezoelectric element PD1, when the active region is formed between the electrode layer 10c and the electrode layer 10d, the magnitude of the electric potential applied to the pair of electrodes 11a4 and 11b4 may be different from the magnitude of the electric potential applied to the pair of electrodes 12a4 and 12b4.

The piezoelectric element PD1 increases the degree of freedom of the magnitude of the electric potential applied to the pair of electrodes 11a4 and 11b4 and the pair of electrodes 12a4 and 12b4, as compared with a configuration in which the electrode layer 10c includes a plurality of electrodes and the electrode layer 10d includes one electrode.

As a result, the piezoelectric element PD1 improves the drive characteristics of the piezoelectric element.

In the piezoelectric element PD1, the electrode layer 10a includes the plurality of connection conductors 16a1 and 16b1 exposed at the side surface 1c and the plurality of connection conductors 17a1 and 17b1 exposed at the side surface 1d. The electrode layer 10b includes the plurality of connection conductors 16a2 and 16b2 exposed at the side surface 1c and the plurality of connection conductors 17a2 and 17b2 exposed at the side surface 1d. The electrode layer 10c includes the plurality of connection conductors 16a3 and 16b3 exposed at the side surface 1c and the plurality of connection conductors 17a3 and 17b3 exposed at the side surface 1d. The electrode layer 10d includes the plurality of connection conductors 16a4 and 16b4 exposed at the side surface 1c and the plurality of connection conductors 17a4 and 17b4 exposed at the side surface 1d.

In the piezoelectric element PD1, the degree of freedom of the magnitude of the electric potential applied to each of the electrode layers 10a, 10b, 10c, and 10d further increases. The piezoelectric element PD1 certainly improves the drive characteristics of the piezoelectric element.

In the piezoelectric element PD1, the first shortest distance L1 in the electrode layer 10a is different from the second shortest distance L2 in the electrode layer 10b. The first shortest distance L1 in the electrode layer 10c is different from the second shortest distance L2 in the electrode layer 10d.

In the piezoelectric element PD1, the degree of freedom of the magnitude of the electric potential applied to each of the electrode layers 10a, 10b, 10c, and 10d further increases. The piezoelectric element PD1 more certainly improves the drive characteristics of the piezoelectric element.

In the piezoelectric element PD1, the first shortest distance L1 is smaller than the second shortest distance L2.

In the piezoelectric element PD1, the degree of freedom of the magnitude of the electric potential applied to each of the electrode layers 10a, 10b, 10c, and 10d further increases. The piezoelectric element PD1 still more certainly improves the drive characteristics of the piezoelectric element.

The piezoelectric element PD1 includes the external electrodes 20a, 20b, 20c, and 20d disposed on the side surface 1c, and the external electrodes 20e, 20f, 20g, and 20h disposed on the side surface 1d. The piezoelectric element PD1 applies a voltage to the connection conductors 16a1, 16b1, 16a2, 16b2, 16a3, 16b3, 16a4, 16b4, 17a1, 17b1, 17a2, 17b2, 17a3, 17b3, 17a4, and 17b4 included in the electrode layers 10a, 10b, 10c, and 10d through the external electrodes 20a, 20b, 20c, 20d, 20e, 20f, 20g, and 20h.

The piezoelectric element PD1 applies a voltage to the connection conductors 16a1 included in the electrode layers 10a through the external electrodes 20b. The piezoelectric element PD1 applies a voltage to the connection conductors 16b1 included in the electrode layers 10a through the external electrodes 20c. The piezoelectric element PD1 applies a voltage to the connection conductors 16a2 included in the electrode layers 10b through the external electrodes 20a. The piezoelectric element PD1 applies a voltage to the connection conductors 16b2 included in the electrode layers 10b through the external electrodes 20d. The piezoelectric element PD1 applies a voltage to the connection conductors 16a3 included in the electrode layers 10c through the external electrodes 20b. The piezoelectric element PD1 applies a voltage to the connection conductors 16b3, included in the electrode layers 10c through the external electrodes 20c. The piezoelectric element PD1 applies a voltage to the connection conductors 16a4 included in the electrode layers 10d through the external electrodes 20a. The piezoelectric element PD1 applies a voltage to the connection conductors 16b4 included in the electrode layers 10d through the external electrodes 20d.

The piezoelectric element PD1 applies a voltage to the connection conductors 17a1 included in the electrode layers 10a through the external electrodes 20f. The piezoelectric element PD1 applies a voltage to the connection conductors 17b1 included in the electrode layers 10a through the external electrodes 20g. The piezoelectric element PD1 applies a voltage to the connection conductors 17a2 included in the electrode layers 10b through the external electrodes 20e. The piezoelectric element PD1 applies a voltage to the connection conductors 17b2 included in the electrode layers 10b through the external electrodes 20h. The piezoelectric element PD1 applies a voltage to the connection conductors 17a3 included in the electrode layers 10c through the external electrodes 20f. The piezoelectric element PD1 applies a voltage to the connection conductors 17b3 included in the electrode layers 10c through the external electrodes 20g. The piezoelectric element PD1 applies a voltage to the connection conductors 17a4 included in the electrode layers 10d through the external electrodes 20e. The piezoelectric element PD1 applies a voltage to the connection conductors 17b4 included in the electrode layers 10d through the external electrodes 20h.

In the piezoelectric element PD1, the external electrode 20a, the external electrode 20b, the external electrode 20c, and the external electrode 20d are positioned in the order of the external electrode 20a, the external electrode 20b, the external electrode 20c, and the external electrode 20d in a direction from the end surface 1e toward the end surface 1f of the third direction D3. The external electrode 20e, the external electrode 20f, the external electrode 20g, and the external electrode 20h are positioned in the order of the external electrode 20e, the external electrode 20f, the external electrode 20g, and the external electrode 20h in a direction from the end surface 1e toward the end surface 1f.

In the piezoelectric element PD1, a magnitude of the electric potential applied to each electrode layer 10a, 10b, 10c, and 10d tends to be easily controlled through the first to eighth external electrodes 20a, 20b, 20c, 20d, 20e, 20f, 20g, and 20h.

In the piezoelectric element PD1, in the electrode layers 10b and 10c, one of the pair of electrodes 12a2 and 12b2 and the other of the pair of electrodes 11a2 and 11b2 are adjacent to the end surface 1e, and one of the pair of electrodes 11a2 and 11b2 and the other of the pair of electrodes 12a2 and 12b2 are adjacent to the end surface 1f. In the electrode layers 10a and 10d, the other of the pair of electrodes 11a4 and 11b4 and one of the pair of electrodes 12a4 and 12b4 are adjacent to the end surface 1e, and the other of the pair of electrodes 12a4 and 12b4 and one of the pair of electrodes 11a4 and 11b4 are adjacent to the end surface 1f.

The piezoelectric element PD1 more certainly improves the drive characteristics of the piezoelectric element.

In the piezoelectric element PD1, the positions of the end edges 11c1 and 11d1 in the third direction D3 are different from the positions of the end edges 17c1 and 17d1 in the third direction D3. The positions of the end edges 11e1 and 11f1 in the third direction D3 are different from the positions of the end edges 16e1 and 16f1 in the third direction D3. The positions of the end edges 12c1 and 12d1 in the third direction D3 are different from the positions of the end edges 16c1 and 16d1 in the third direction D3. The positions of the end edges 12e1 and 12f1 in the third direction D3 are different from the positions of the end edges 17e1 and 17f1 in the third direction D3.

The positions of the end edges 11c2 and 11d2 in the third direction D3 are different from the positions of the end edges 17c2 and 17d2 in the third direction D3. The positions of the end edges 11e2 and 11f2 in the third direction D3 are different from the positions of the end edges 16e2 and 16f2 in the third direction D3. The positions of the end edges 12c2 and 12d2 in the third direction D3 are different from the positions of the end edges 16c2 and 16d2 in the third direction D3. The positions of the end edges 12e2 and 12f2 in the third direction D3 are different from the positions of the end edges 17e2 and 17f2 in the third direction D3.

The positions of the end edges 11c3 and 11d3 in the third direction D3 are different from the positions of the end edges 17c3 and 17d3 in the third direction D3. The positions of the end edges 11e3 and 11f3 in the third direction D3 are different from the positions of the end edges 16e3 and 16f3 in the third direction D3. The positions of the end edges 12c3 and 12d3 in the third direction D3 are different from the positions of the end edges 16c3 and 16d3 in the third direction D3. The positions of the end edges 12e3 and 12f3 in the third direction D3 are different from the positions of the end edges 17e3 and 17f3 in the third direction D3.

The positions of the end edges 11c4 and 11d4 in the third direction D3 are different from the positions of the end edges 17c4 and 17d4 in the third direction D3. The positions of the end edges 11e4 and 11f4 in the third direction D3 are different from the positions of the end edges 16e4 and 16f4 in the third direction D3. The positions of the end edges 12c4 and 12d4 in the third direction D3 are different from the positions of the end edges 16c4 and 16d4 in the third direction D3. The positions of the end edges 12e4 and 12f4 in the third direction D3 are different from the positions of the end edges 17e4 and 17f4 in the third direction D3.

The piezoelectric element PD1 still more certainly improves drive characteristics of the piezoelectric element.

In the piezoelectric element PD1, the fourth electrode layer included in one of the plurality of electrode layer groups and the first electrode layer included in the other of the plurality of electrode layer groups are adjacent to each other.

The piezoelectric element PD1 still more certainly improves the drive characteristics of the piezoelectric element.

Although the examples of the present disclosure have been described above, the present disclosure is not necessarily limited to the above-described examples, and various modifications can be made without departing from the gist thereof.

For example, the order in which the electrode layers 10a to 10d are disposed in each of the electrode layer groups EG1 and EG2 is not limited to the above-described order.

In each of the electrode layer groups EG1 and EG2, as a modification, the electrode layers 10a to 10d may be disposed in the first direction D1 in the order of the electrode layer 10a, the electrode layer 10d, the electrode layer 10c, and the electrode layer 10b. In this case, for example, the electrode layer 10b of the electrode layer group EG1 and the electrode layer 10a of the electrode layer group EG2 are adjacent to each other. The electrode layer group EG3 may include an electrode layer 10a. In the modification, when the electrode layer 10a includes a first electrode layer, the electrode layer 10d includes a second electrode layer, the electrode layer 10c includes a third electrode layer, and the electrode layer 10b includes a fourth electrode layer.

In each of the electrode layer groups EG1 and EG2, as another modification, the electrode layers 10a to 10d may be disposed in the first direction D1 in the order of the electrode layer 10c, the electrode layer 10b, the electrode layer 10a, and the electrode layer 10d. In this case, for example, the electrode layer 10d of the electrode layer group EG1 and the electrode layer 10c of the electrode layer group EG2 are adjacent to each other. The electrode layer group EG3 may include an electrode layer 10c. In the modification, when the electrode layer 10c includes a first electrode layer, the electrode layer 10b includes a second electrode layer, the electrode layer 10a includes a third electrode layer, and the electrode layer 10d includes a fourth electrode layer.

In each of the electrode layer groups EG1 and EG2, as still another modification, the electrode layers 10a to 10d may be disposed in the first direction D1 in the order of the electrode layer 10c, the electrode layer 10d, the electrode layer 10a, and the electrode layer 10b. In this case, for example, the electrode layer 10b of the electrode layer group EG1 and the electrode layer 10c of the electrode layer group EG2 are adjacent to each other. The electrode layer group EG3 may include an electrode layer 10c. In the modification, when the electrode layer 10c includes a first electrode layer, the electrode layer 10d includes a second electrode layer, the electrode layer 10a includes a third electrode layer, and the electrode layer 10b includes a fourth electrode layer.

The number of electrode layer groups included in the piezoelectric element PD1 is not limited to the above-described number. For example, the number of electrode layer groups included in the piezoelectric element PD1 may be one. In this case, the piezoelectric element PD1 may include only one of the electrode layer group EG1 and the electrode layer group EG2. The piezoelectric element PD1 may include at least four electrode layers 10a, 10b, 10c, and 10d.

In the piezoelectric element PD1, the first shortest distance L1 may not be different from the second shortest distance L2. In the configuration in which the first shortest distance L 1 is different from the second shortest distance L2, as described above, the degree of freedom of the magnitude of the electric potential applied to each of the electrode layers 10a, 10b, 10c, and 10d further increases. As a result, the piezoelectric element PD1 more certainly improves the drive characteristics.

The positions of the end edges 11c2 and 11d2 in the third direction D3 are different from the positions of the end edges 17c2 and 17d2 in the third direction D3. The positions of the end edges 11e2 and 11f2 in the third direction D3 and the positions of the end edges 16e2 and 16f2 in the third direction D3 may not be different from each other. The positions of the end edges 12c2 and 12d2 in the third direction D3 are different from the positions of the end edges 16c2 and 16d2 in the third direction D3. The positions of the end edges 12e2 and 12f2 in the third direction D3 and the positions of the end edges 17e2 and 17f2 in the third direction D3 may not be different from each other.

The positions of the end edges 11c3 and 11d3 in the third direction D3 are different from the positions of the end edges 17c3 and 17d3 in the third direction D3. The positions of the end edges 11e3 and 11f3 in the third direction D3 and the positions of the end edges 16e3 and 16f3 in the third direction D3 may not be different from each other. The positions of the end edges 12c3 and 12d3 in the third direction D3 are different from the positions of the end edges 16c3 and 16d3 in the third direction D3. The positions of the end edges 12e3 and 12f3 in the third direction D3 and the positions of the end edges 17e3 and 17f3 in the third direction D3 may not be different from each other.

The positions of the end edges 11c4 and 11d4 in the third direction D3 are different from the positions of the end edges 17c4 and 17d4 in the third direction D3. The positions of the end edges 11e4 and 11f4 in the third direction D3 and the positions of the end edges 16e4 and 16f4 in the third direction D3 may not be different from each other. The positions of the end edges 12c4 and 12d4 in the third direction D3 and the positions of the end edges 16c4 and 16d4 in the third direction D3 may not be different from each other. The positions of the end edges 12e4 and 12f4 in the third direction D3 and the positions of the end edges 17e4 and 17f4 in the third direction D3 may not be different from each other.

The configuration in which these positions are different from each other more certainly improves the drive characteristics of the piezoelectric element PD1 as described above.

What is claimed is:

1. A piezoelectric element comprising:
a piezoelectric body; and
at least one electrode layer group including a first electrode layer, a second electrode layer, a third electrode layer, and a fourth electrode layer disposed in the piezoelectric body,
wherein each of the first electrode layer, the second electrode layer, the third electrode layer, and the fourth electrode layer includes a pair of first electrodes physically and electrically separated from each other in the piezoelectric body, and a pair of second electrodes physically and electrically connected to each other in the piezoelectric body,
the first electrodes included in the first electrode layer oppose the second electrodes included in the second electrode layer with a part of the piezoelectric body, and the second electrodes included in the first electrode layer oppose the first electrodes included in the second electrode layer with a part of the piezoelectric body, and
the first electrodes included in the second electrode layer oppose the first electrodes included in the third electrode layer with a part of the piezoelectric body, and the second electrodes included in the second electrode layer oppose the second electrodes included in the third electrode layer with a part of the piezoelectric body, and
the first electrodes included in the third electrode layer oppose the second electrodes included in the fourth electrode layer with a part of the piezoelectric body, and the second electrodes included in the third electrode layer oppose the first electrodes included in the fourth electrode layer with a part of the piezoelectric body.

2. The piezoelectric element according to claim 1, wherein
the piezoelectric body includes a first main surface and a second main surface opposing each other in a first direction, a first side surface and a second side surface opposing each other in a second direction, and a first end surface and a second end surface opposing each other in a third direction,
each of the first electrode layer, the second electrode layer, the third electrode layer, and the fourth electrode layer includes a plurality of first connection conductors exposed at the first side surface and a plurality of second connection conductors exposed at the second side surface,
each of the plurality of first connection conductors is exposed at the first side surface at different positions in the third direction,
each of the plurality of second connection conductors is exposed at the second side surface at different positions in the third direction,
in each of the first electrode layer, the second electrode layer, the third electrode layer, and the fourth electrode layer, each of one of the pair of first electrodes and one of the pair of second electrodes is adjacent to the first side surface and physically and electrically connected to a corresponding first connection conductor among the plurality of first connection conductors, and
in each of the first electrode layer, the second electrode layer, the third electrode layer, and the fourth electrode layer, each of another of the pair of first electrodes and another of the pair of second electrodes is adjacent to the second side surface and physically and electrically connected to a corresponding second connection conductor among the plurality of second connection conductors.

3. The piezoelectric element according to claim 2, wherein
a first shortest distance between the first connection conductor connected to the one of the pair of second electrodes and the second connection conductor connected to the other of the pair of second electrodes in the first electrode layer and the third electrode layer is different from a second shortest distance between the second connection conductor connected to the one of the pair of second electrodes and the first connection conductor connected to the other of the pair of second electrodes in the second electrode layer and the fourth electrode layer.

4. The piezoelectric element according to claim 3, wherein
the first shortest distance is smaller than the second shortest distance.

5. The piezoelectric element according to claim 2, further comprising:
a first external electrode, a second external electrode, a third external electrode, and a fourth external electrode disposed on the first side surface;
and
a fifth external electrode, a sixth external electrode, a seventh external electrode, and an eighth external electrode disposed on the second side surface,
wherein the first external electrode is connected to the first connection conductor included in the second electrode layer and connected to the one of the pair of first electrodes, and is connected to the first connection conductor included in the fourth electrode layer and connected to the one of the pair of second electrodes,
the second external electrode is connected to the first connection conductor included in the first electrode layer and connected to the one of the pair of second electrodes, and is connected to the first connection conductor included in the third electrode layer and connected to the one of the pair of first electrodes,
the third external electrode is connected to the first connection conductor included in the first electrode layer and connected to the one of the pair of first electrodes, and is connected to the first connection conductor included in the third electrode layer and connected to the one of the pair of second electrodes,
the fourth external electrode is connected to the first connection conductor included in the second electrode layer and connected to the one of the pair of second electrodes, and is connected to the first connection conductor included in the fourth electrode layer and connected to the one of the pair of first electrodes,
the fifth external electrode is connected to the second connection conductor included in the second electrode layer and connected to the other of the pair of second electrodes, and is connected to the second connection conductor included in the fourth electrode layer and connected to the other of the pair of first electrodes,
the sixth external electrode is connected to the second connection conductor included in the first electrode layer and connected to the other of the pair of first electrodes, and is connected to the second connection conductor included in the third electrode layer and connected to the other of the pair of second electrodes,
the seventh external electrode is connected to the second connection conductor included in the first electrode layer and connected to the other of the pair of second electrodes, and is connected to the second connection conductor included in the third electrode layer and connected to the other of the pair of first electrodes, and
the eighth external electrode is connected to the second connection conductor included in the second electrode layer and connected to the other of the pair of first electrodes, and is connected to the second connection conductor included in the fourth electrode layer and connected to the other of the pair of second electrodes.

6. The piezoelectric element according to claim 5, wherein
the first external electrode, the second external electrode, the third external electrode, and the fourth external electrode are positioned in an order of the first external electrode, the second external electrode, the third external electrode, and the fourth external electrode in a direction from the first end surface toward the second end surface of the third direction, and
the fifth external electrode, the sixth external electrode, the seventh external electrode, and the eighth external electrode are positioned in an order of the fifth external electrode, the sixth external electrode, the seventh external electrode, and the eighth external electrode in the direction from the first end surface toward the second end surface.

7. The piezoelectric element according to claim 5, wherein
in the second electrode layer and the third electrode layer, the one of the pair of second electrodes and the other of the pair of first electrodes are adjacent to the first end surface, and the one of the pair of first electrodes and the other of the pair of second electrodes are adjacent to the second end surface, and
in the first electrode layer and the fourth electrode layer, the other of the pair of first electrodes and the one of the pair of second electrodes are adjacent to the first end surface, and the other of the pair of second electrodes and the one of the pair of first electrodes are adjacent to the second end surface.

8. The piezoelectric element according to claim 5, wherein
each of the first electrodes includes a pair of first end edges opposing each other in the third direction,
each of the second electrodes includes a pair of second end edges opposing each other in the third direction,
each of the first connection conductors includes a pair of third end edges opposing each other in the third direction,
each of the second connection conductors includes a pair of fourth end edges opposing each other in the third direction,
in the first electrode and the first connection conductor connected to each other, positions of the pair of first end edges in the third direction are different from positions of the pair of third end edges in the third direction,
in the second electrode and the first connection conductor connected to each other, positions of the pair of second end edges in the third direction are different from positions of the pair of third end edges in the third direction,
in the first electrode and the second connection conductor connected to each other, positions of the pair of first end edges in the third direction are different from positions of the pair of fourth end edges in the third direction, and
in the second electrode and the second connection conductor connected to each other, positions of the pair of second end edges in the third direction are different from positions of the pair of fourth end edges in the third direction.

9. The piezoelectric element according to claim 1, wherein
the at least one electrode layer group includes a plurality of electrode layer groups each including the first electrode layer, the second electrode layer, the third electrode layer, and the fourth electrode layer, and
the fourth electrode layer included in one of the plurality of electrode layer groups and the first electrode layer included in another of the plurality of electrode layer groups are adjacent to each other.
